(19) United States
(12) Patent Application Publication
(10) Pub. No.: US 2009/0218743 A1
(43) Pub. Date: Sep. 3, 2009

(54) Substrate holding apparatus, exposure apparatus, exposing method, device fabricating method, plate member, and wall

(75) Inventors: Tomoharu Fujiwara, Gyoda-shi (JP); Hiroyuki Nagasaka, Kumagaya-shi (JP)

Correspondence Address: OLIFF & BERRIDGE, PLC, P.O. BOX 320850, ALEXANDRIA, VA, 22320-4850, US

(73) Assignee: NIKON CORPORATION, TOKYO (JP)

(21) Appl. No.: 12/379,229

(22) Filed: Feb. 17, 2009

Related U.S. Application Data
(60) Provisional application No. 61/064,356, filed on Feb. 29, 2008.

(51) Int. Cl. H01L 21/687; G03B 27/58

(52) U.S. Cl. 269/287; 355/72

(57) ABSTRACT

A substrate holding apparatus holds a substrate that is exposed by exposure light that passes through a liquid. The substrate holding apparatus comprises: an opening; and a first holding part, which has a holding surface for holding the substrate inside the opening. At least part of an edge part that defines the opening has a first surface and a second surface, which is provided above and is nonparallel to the first surface. The second surface extends from a boundary part between the first surface and the second surface both upward and toward the outer side with respect to a center of the opening. The boundary part between the first surface and the second surface is substantially the same height as or higher than a front surface of the substrate, which is held by the first holding part.

### CROSS-REFERENCE TO RELATED APPLICATION

This application is a non-provisional application claiming priority to and the benefit of U.S. provisional application No. 61/064,356, filed Feb. 29, 2008. The entire contents of which are incorporated herein by reference.

### BACKGROUND

1. Field of the Invention

The present invention relates to a substrate holding apparatus, an exposure apparatus, an exposing method, a device fabricating method, a plate member, and a wall.

2. Description of Related Art

Among exposure apparatuses used in photolithography, one that is well known to those skilled in the art is an immersion exposure apparatus that exposes a substrate with exposure light that passes through a liquid (for example, European Patent Application Publication No. 1860684, U.S. Patent Application Publication No. 2006/0139614, U.S. Pat. No. 7,199,858). Exposure apparatuses comprise a substrate holding apparatus that holds the substrate, and expose the substrate when it is held thereby. With regard to immersion exposure apparatuses, if the liquid penetrates a gap between the substrate and a member disposed around the edge of the substrate, then it is possible that various kinds of problems will occur. For example, if the liquid that penetrates the gap vaporizes, then the substrate could, for example, thermally deform owing to the liquid's heat of vaporization, or an adhered residue (e.g., a watermark) of the liquid could form on the substrate. If such problems arise, then it is possible that exposure failures, such as defects in the pattern formed on the substrate, will occur. These potential problems could also result in the production of defective devices.

As discussed above, if the liquid penetrates via the gap formed around the edge of the substrate, then all manner of problems could arise; therefore, there is a demand for an improvement that can inhibit the penetration of the liquid via the gap.

A purpose of some aspects of the present invention is to provide a substrate holding apparatus that can inhibit liquid from penetrating via a gap formed at least partly around the edge of the substrate. Another purpose is to provide an immersion exposure apparatus that can prevent exposure failures, and an exposing method. Yet another purpose is to provide a device fabricating method that can prevent the production of defective devices. Finally, yet another purpose is to provide a plate member that can inhibit the liquid from penetrating via the gap formed at least partly around the edge of the substrate.

### SUMMARY

A first aspect of the invention provides a substrate holding apparatus, which holds a substrate that is exposed by exposure light that passes through a liquid, comprising: an opening; and a first holding part, which has a holding surface for holding the substrate inside the opening; wherein, at least part of an edge part that defines the opening has a first surface and a second surface, which is provided above and is nonparallel to the first surface; the second surface extends from a boundary part between the first surface and the second surface both upward and toward the outer side with respect to a center of the opening; and the boundary part between the first surface and the second surface is substantially the same height as or higher than a front surface of the substrate, which is held by the first holding part.

A second aspect of the invention provides a substrate holding apparatus, which holds a substrate that is exposed by exposure light that passes through a liquid, comprising: an opening; and a first holding part, which has a holding surface for holding the substrate inside the opening; wherein, at least part of an edge part that defines the opening has a first surface and a second surface, which is provided above the first surface; the second surface extends from a boundary part between the first surface and the second surface both upward and toward the outer side with respect to a center of the opening; and the first surface extends from the boundary part between the first surface and the second surface both downward and toward the outer side with respect to a center of the opening.

A third aspect of the invention provides a substrate holding apparatus, which holds a substrate that is exposed by exposure light that passes through a liquid, comprising: an opening; and a first holding part, which has a holding surface for holding the substrate inside the opening; wherein, at least part of an edge part that defines the opening has a first surface, a second surface, which is provided above the first surface, and a third surface, which is provided below the first surface; the second surface extends from a boundary part between the first surface and the second surface both upward and toward the outer side with respect to a center of the opening; the third surface extends from a boundary part between the first surface and the third surface both downward and toward the outer side with respect to the center of the opening; and an angle formed between an axis perpendicular to the holding surface of the first holding part and the second surface is greater than an angle formed between the axis and the third surface.

A fourth aspect of the invention provides a substrate holding apparatus, which holds a substrate that is exposed by exposure light that passes through a liquid, comprising: an opening; and a first holding part, which has a holding surface for holding the substrate inside the opening; wherein, at least part of an edge part that defines the opening has a first surface, a second surface, which is provided above the first surface, and a third surface, which is provided below the first surface; the second surface extends from a boundary part between the first surface and the second surface both upward and toward the outer side with respect to a center of the opening; the third surface extends from a boundary part between the first surface and the third surface both downward and toward the outer side with respect to the center of the opening; and the third surface is larger than the first surface in directions perpendicular to the holding surface of the first holding part.

A fifth aspect of the invention provides a substrate holding apparatus, which holds a substrate that is exposed by exposure light that passes through a liquid, comprising: an opening; and a first holding part, which has a holding surface for holding the substrate inside the opening; wherein, at least part of an edge part that defines the opening has a first inclined surface part and a second inclined surface part, which is provided above the first inclined surface part; the more spaced apart the first inclined surface part becomes from the substrate held by the first holding part, the lower it becomes; the more spaced apart the second inclined surface part becomes from the substrate held by the first holding part, the higher it becomes; and the first inclined surface part is larger than the second inclined surface part in directions that are perpendicular to the holding surface of the first holding part.

A sixth aspect of the invention provides an exposure apparatus that exposes a substrate through a liquid, comprising: a substrate holding apparatus according to any one aspect of the first through fifth aspects; wherein, the substrate is held by the substrate holding apparatus.

A seventh aspect of the invention provides a device fabricating method, comprising the steps of: exposing a substrate using the exposure apparatus according to the sixth aspect; and developing the exposed substrate.

An eighth aspect of the invention provides an exposing method, comprising the steps of: holding a substrate by a substrate holding apparatus according to any aspect of the first through fifth aspects, and radiating exposure light to the substrate, which is held by the substrate holding apparatus, through a liquid.

A ninth aspect of the invention provides a device fabricating method, comprising the steps of: exposing a substrate using an exposing method according to the eighth aspect; and developing the exposed substrate.

A tenth aspect of the invention provides a plate member, which is disposed around a substrate that is exposed through a liquid, comprising: an opening, which is for disposing the substrate therein; and a front surface, which is formed around the opening; wherein, at least part of an edge part, which defines the opening, has a first surface and a second surface, which is provided so that it adjoins the first surface; the first surface extends from a boundary part between the first surface and the second surface both in a first direction that is perpendicular to the front surface and toward the outer side with respect to a center of the opening; and the second surface extends from the boundary part between the first surface and the second surface both in a second direction, which is the opposite of the first direction, and toward the outer side with respect to the center of the opening.

An eleventh aspect of the invention provides a plate member, which is disposed around a substrate that is exposed through a liquid, comprising: an opening, which is for disposing the substrate therein; and a front surface, which is formed around the opening; wherein, at least part of an edge part, which defines the opening, has a first surface, a second surface, which is provided adjoining one side of the first surface, and a third surface, which is provided adjoining another side of the first surface; the second surface extends from a boundary part between the first surface and the second surface both in a first direction that is perpendicular to the front surface and toward the outer side with respect to a center of the opening; the third surface extends from a boundary part between the first surface and the third surface both in a second direction, which is the opposite of the first direction, and toward the outer side with respect to the center of the opening; and an angle formed between an axis that is perpendicular to the front surface and the second surface is larger than an angle formed between the axis and the third surface.

A twelfth aspect of the invention provides a plate member, which is disposed around a substrate that is exposed through a liquid, comprising: an opening, which is for disposing the substrate therein; and a front surface, which is formed around the opening; wherein, at least part of an edge part, which defines the opening, has a first surface, a second surface, which is provided adjoining one side of the first surface, and a third surface, which is provided adjoining another side of the first surface; the second surface extends from a boundary part between the first surface and the second surface both in a first direction that is perpendicular to the front surface and toward the outer side with respect to a center of the opening; the third surface extends from a boundary part between the first surface and the third surface both in a second direction, which is the opposite of the first direction, and toward the outer side with respect to the center of the opening; and the third surface is larger than the first surface in directions that are parallel to the first and second directions.

A thirteenth aspect of the invention provides a wall that surrounds at least a part of a substrate in an immersion exposure apparatus, the wall comprising: a first gradient surface that has a declination to the substrate; and a corner that is at a lower end of the first gradient surface and that is relatively near to the substrate, the corner being located at a substantially same height position as a surface of the substrate or at a higher position than the surface of the substrate.

A fourteenth aspect of the invention provides a wall that surrounds at least a part of a substrate in an immersion exposure apparatus, the wall comprising: a first gradient portion that has a declination to the substrate; a second gradient portion that is lower than the first gradient portion and has a inclination up to the substrate; and a corner that is at a lower end of the first gradient portion and that is substantially nearest to the substrate, the corner located at a height position relatively near to a surface of the substrate.

According to some aspects of the present invention, it is possible to inhibit the penetration of a liquid via a gap formed at least partly around the edge of a substrate. In addition, it is possible, according to the present invention, to prevent the occurrence of exposure failures. Finally, according to some aspects of the present invention, it is possible to prevent the production of defective devices.

### BRIEF DESCRIPTION OF THE DRAWINGS

FIG. 1 is a schematic block diagram that shows one example of an exposure apparatus according to a first embodiment.

FIG. 2 is a side cross sectional view that shows the vicinity of a substrate table and a liquid immersion member according to the first embodiment.

FIG. 3 is a plan view of the substrate table according to the first embodiment, viewed from above.

FIG. 4 is a partial, enlarged, side cross sectional view of a plate member according to the first embodiment.

FIG. 5A includes schematic drawings for explaining the behavior of the liquid that penetrates the gap.

FIG. 5B includes schematic drawings for explaining the behavior of the liquid that penetrates the gap.

FIG. 6 is a schematic drawing for explaining the function of the plate member according to a comparative example.

FIG. 7 is a schematic drawing for explaining the function of the plate member according to a comparative example.

FIG. 8 is a schematic drawing for explaining the function of the plate member according to the first embodiment.

FIG. 9 is a partial, enlarged, side cross sectional view of the plate member according to a second embodiment.

FIG. 10 is a schematic drawing for explaining the function of the plate member according to the second embodiment.

FIG. 11 is a partial, enlarged, side cross sectional view of the plate member according to a third embodiment.

FIG. 12 is a partial, enlarged, side cross sectional view of the plate member according to a fourth embodiment.

FIG. 13 is a partial, enlarged, side cross sectional view of the plate member according to a fifth embodiment.

FIG. 14 is a side cross sectional view that shows one example of the substrate table according to a sixth embodiment.

FIG. 15 is a side cross sectional view that shows one example of the substrate table according to a seventh embodiment.

FIG. 16 is a flow chart for explaining one example of a process of fabricating a microdevice.

### DESCRIPTION OF EMBODIMENTS

The following text explains the embodiments of the present invention referencing the drawings, but the present invention is not limited thereto. The explanation defines an XYZ orthogonal coordinate system, and the positional relationships among members are explained referencing this system. Prescribed directions within the horizontal plane are the X axial directions, directions orthogonal to the X axial directions in the horizontal plane are the Y axial directions, and directions orthogonal to the X axial directions and the Y axial directions (i.e., the vertical directions) are the Z axial directions. In addition, the rotational (inclination) directions around the X, Y, and Z axes are the θX, θY, and θZ directions, respectively.

### First Embodiment

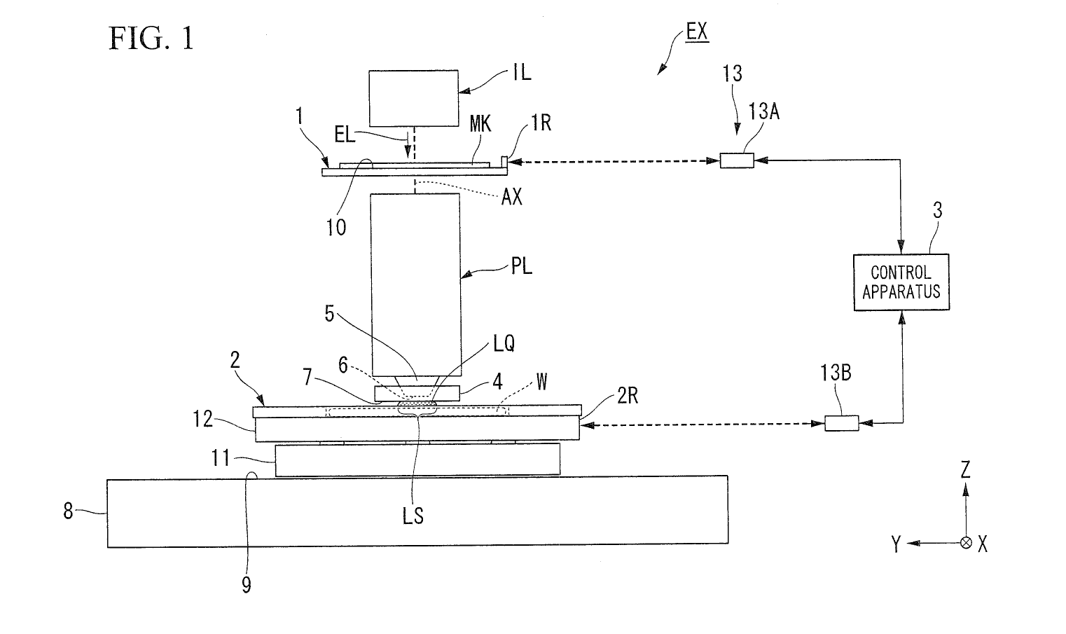

A first embodiment will now be explained. FIG. 1 is a schematic block diagram that shows an exposure apparatus EX according to the first embodiment. In FIG. 1, the exposure apparatus EX comprises: a movable mask stage 1, which holds a mask MK; a movable substrate stage 2, which holds a substrate W; an illumination system IL, which illuminates the mask MK with exposure light EL; a projection optical system PL, which projects onto the substrate W an image of a pattern of the mask MK illuminated by the exposure light EL; and a control apparatus 3, which controls the operation of the entire exposure apparatus EX.

The mask MK includes a reticle on which a device pattern to be projected to the substrate W is formed. The mask MK may be, for example, a light transmitting type mask wherein a light shielding film made of chrome and the like is used to form a prescribed pattern on a transparent plate (e.g., a glass plate). Furthermore, the mask MK may alternatively be a reflection type mask. The substrate W is a substrate for fabricating a device. The substrate W comprises a base material (e.g., a semiconductor wafer, such as a silicon wafer) and a photosensitive film that is formed thereon. The photosensitive film is made of a photosensitive material (photoresist).

The exposure apparatus EX of the present embodiment is an immersion exposure apparatus that exposes the substrate W with the exposure light EL that passes through a liquid LQ. The exposure apparatus EX comprises a liquid immersion member 4, which is capable of forming an immersion space LS such that at least part of the optical path of the exposure light EL is filled with the liquid LQ. The immersion space LS is a space that is filled with the liquid LQ. In the present embodiment, water (pure water) is used as the liquid LQ.

In the present embodiment, the immersion space LS is formed so that the optical path of the exposure light EL that emerges from a last optical element 5, which is the optical element of a plurality of optical elements of the projection optical system PL closest to the image plane of the projection optical system PL, is filled with the liquid LQ. The last optical element 5 comprises an emergent surface 6 that emits the exposure light EL toward the image plane of the projection optical system PL. The immersion space LS is formed so that the optical path between the last optical element 5 and an object that is disposed such that its position opposes the emergent surface 6 of the last optical element 5 is filled with the liquid LQ. The position that opposes the emergent surface 6 includes an irradiation position of the exposure light EL that emerges from the emergent surface 6. In the explanation below, the position that opposes the emergent surface 6 of the last optical element 5 is discretionarily called an exposure position.

The liquid immersion member 4 is disposed in the vicinity of the last optical element 4. The liquid immersion member 5 comprises a lower surface 7. In the present embodiment, the object capable of opposing the emergent surface 6 is also capable of opposing the lower surface 7. The front surface of the object is disposed at the exposure position in advance and opposes at least part of the lower surface 7. When the emergent surface 6 and the front surface of the object are opposed, the last optical element 5 can hold the liquid LQ between the emergent surface 6 and the front surface of the object. In addition, when the lower surface 7 and the front surface of the object are opposed, the liquid immersion member 4 can hold the liquid LQ between the lower surface 7 and the front surface of the object. The immersion space LS is formed by the liquid LQ, which is held between the emergent surface 6 and the lower surface 7 on one side and the front surface of the object on the other side.

The object capable of opposing the emergent surface 6 and the lower surface 7 in the present embodiment includes an object capable of moving within a prescribed plane that includes the exposure position. In the present embodiment, the object includes either the substrate stage 2 or the substrate W, which is held by the substrate stage 2, or both. In the present embodiment, the substrate stage 2 is capable of moving on a guide surface 9 of a base member 8. The guide surface 9 is substantially parallel to the XY plane in the present embodiment. The substrate stage 2 is capable of holding the substrate W and moving along the guide surface 9 within an XY plane that includes the exposure position.

In the present embodiment, the immersion space LS is formed so that part of the area (a local area) of the front surface of the substrate W, which is disposed at a position at which it opposes the emergent surface 6 and the lower surface 7, is covered by the liquid LQ, and an interface (meniscus or edge) of the liquid LQ of the immersion space LS is formed between the front surface of the substrate W and the lower surface 7. Namely, the exposure apparatus EX of the present embodiment adopts a local liquid immersion system wherein the immersion space LS is formed so that part of the area on the substrate W that includes a projection region of the projection optical system PL is covered with the liquid LQ during the exposure of the substrate W.

The illumination system IL illuminates a prescribed illumination area with the exposure light EL, which has a uniform luminous flux intensity distribution. The illumination system IL illuminates at least part of the mask MK disposed in the illumination area with the exposure light EL, which has a uniform luminous flux intensity distribution. Examples of light that can be used as the exposure light EL emitted from the illumination system IL include: deep ultraviolet (DUV) light such as a bright line (g-line, h-line, or i-line) light emitted from, for example, a mercury lamp and KrF excimer laser light (with a wavelength of 248 nm); and vacuum ultraviolet (VUV) light such as ArF excimer laser light (with a wavelength of 193 nm) and F₂ laser light (with a wavelength of 157 nm). In the present embodiment, ArF excimer laser light, which is ultraviolet light (vacuum ultraviolet light), is used as the exposure light EL.

The mask stage 1 comprises a mask holding part 10 that releasably holds the mask MK. In the present embodiment, the mask holding part 10 holds the mask MK so that a patterned surface (lower surface) of the mask MK is substantially parallel with the XY plane. The mask stage 1 is capable of holding the mask MK and moving within the XY plane by the operation of a mask stage drive system that includes actuators, such as linear motors. In the state wherein the mask MK is held by the mask holding part 10, the mask stage 1 is capable of moving in three directions: the X axial, Y axial, and θZ directions.

The projection optical system PL radiates the exposure light EL to the prescribed projection region. The projection optical system PL projects with a prescribed projection magnification an image of the pattern of the mask MK to at least part of the substrate W, which is disposed in the projection region. The projection optical system PL of the present embodiment is a reduction system that has a projection magnification of, for example, ¼, ⅕, or ⅛. Furthermore, the projection optical system PL may alternatively be a unity magnification system or an enlargement system. In the present embodiment, an optical axis AX of the projection optical system PL is substantially parallel to the Z axis. In addition, the projection optical system PL may be a dioptric system that does not include catoptric elements, a catoptric system that does not include dioptric elements, or a catadioptric system that includes both catoptric and dioptric elements. In addition, the projection optical system PL may form either an inverted or an erect image.

The substrate stage 2 comprises a stage main body 11 and a substrate table 12, which is disposed on the stage main body 11 and is capable of holding the substrate W. The stage main body 11 is noncontactually supported by the guide surface 9 via a gas bearing and is capable of moving on the guide surface 9 in the X and Y directions. In the state wherein the substrate stage 2 holds the substrate W, the substrate stage 2 is capable of moving on the light emergent side of the last optical element 5 (on the image plane side of the projection optical system PL) within a prescribed area of the guide surface 9 that includes the position at which the substrate stage 2 opposes the emergent surface 6 and the lower surface 7.

The stage main body 11 is capable of moving on the guide surface 9 within the XY plane by the operation of a coarse motion system that includes actuators, such as linear motors. The substrate table 12 is capable of moving—by the operation of the fine motion system that includes actuators, such as voice coil motors—relative to the stage main body 11 in the Z axial, θX, and θY directions. The substrate table 12, in the state wherein it holds the substrate W, is capable of moving—by the drive of a substrate stage drive system, which includes a coarse motion system and a fine motion system—in six directions: the X axial, Y axial, Z axial, θX, θY, and θZ directions.

An interferometer system 13 measures the positions of the mask stage 1 and the substrate stage 2 within the XY plane. The interferometer system 13 comprises: a laser interferometer 13A, wherein the position of the mask stage 1 within the XY plane is measured using a reflecting surface 1R disposed in the mask stage 1; and a laser interferometer 13B, wherein the position of the substrate stage 2 within the XY plane is measured using a reflecting surface 2R disposed in the substrate stage 2. In addition, a focus and level detection system (not shown) detects the position of the front surface of the substrate W held by the substrate stage 2.

When the substrate W is to be exposed, the interferometer system 13 measures the position of the mask stage 1 and the position of the substrate stage 2. Based on the measurement results of the interferometer system 13, the control apparatus 3 positionally controls the mask MK, which is held by the mask stage 1. In addition, based on the measurement results of the interferometer system 13 and the detection results of the focus and level detection system, the control apparatus 3 positionally controls the substrate W, which is held by the substrate stage 2.

The exposure apparatus EX of the present embodiment is a scanning type exposure apparatus (a so-called scanning stepper) that projects the image of the pattern of the mask MK onto the substrate W while synchronously moving the mask MK and the substrate W in prescribed scanning directions. When the substrate W is to be exposed, the control apparatus 3 controls the mask stage 1 and the substrate stage 2 so as to move the mask MK and the substrate W in the prescribed scanning directions within the XY plane, which is orthogonal to the optical path (the optical axis AX) of the exposure light EL. In the present embodiment, the scanning directions (the synchronous movement directions) of the substrate W and the mask MK are the Y axial directions. The control apparatus 3 radiates the exposure light EL to the substrate W through the projection optical system PL and the liquid LQ in the immersion space LS on the substrate W while synchronously moving the substrate W in one Y axial direction—relative to the projection region of the projection optical system PL—and the mask MK in the other Y axial direction—relative to the illumination area of the illumination system IL. Thus, the substrate W is exposed with the exposure light EL, and the image of the pattern of the mask MK is projected onto the substrate W.

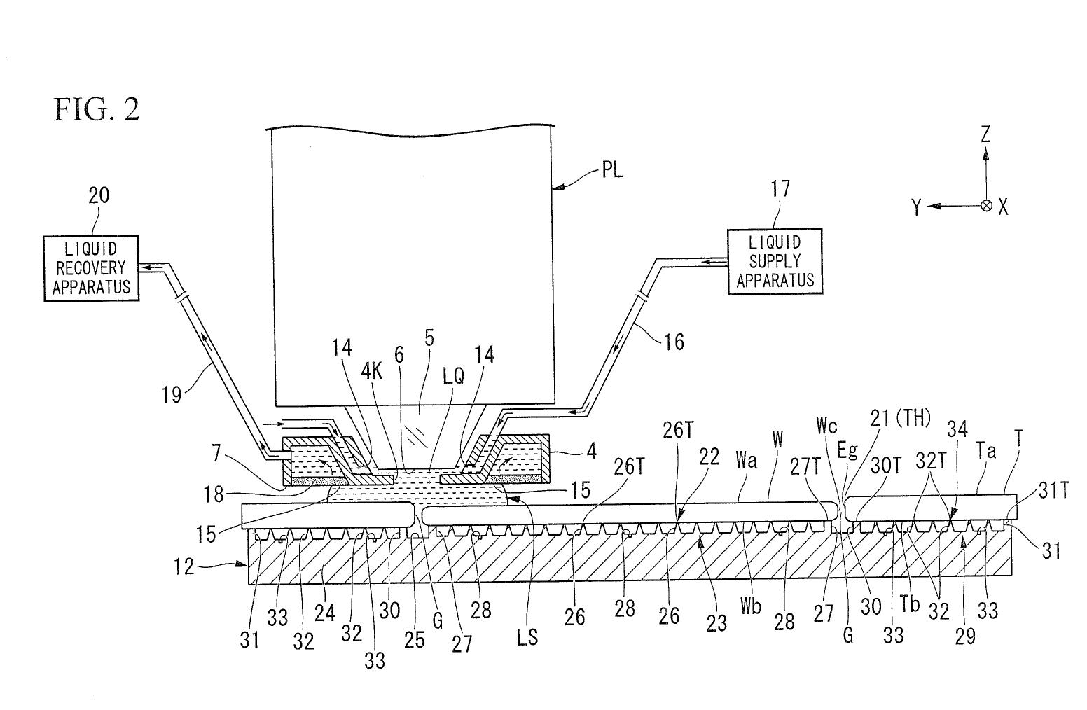

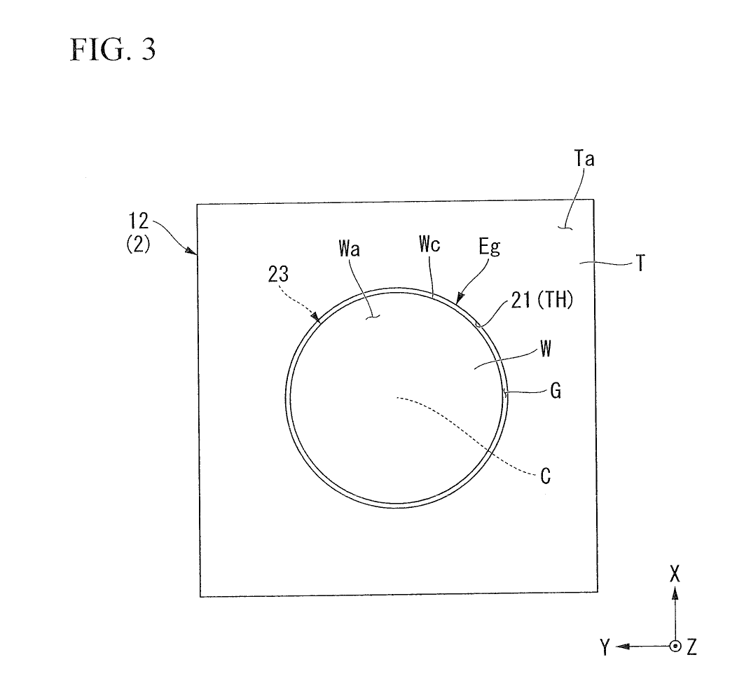

The following text explains the liquid immersion member 4 and the substrate table 12, referencing FIG. 2 and FIG. 3. FIG. 2 is a side cross sectional view that shows the vicinity of the substrate table 12, which is disposed at the exposure position, and FIG. 3 is a plan view of the substrate table 12, viewed from above.

The liquid immersion member 4 is an annular member. The liquid immersion member 4 is disposed around the last optical element 5. As shown in FIG. 2, the liquid immersion member 4 has an opening 4K at a position at which it opposes the emergent surface 6. The liquid immersion member 4 comprises supply ports 14, which are capable of supplying the liquid LQ, and a recovery port 15, which is capable of recovering the liquid LQ.

The supply ports 14 are capable of supplying the liquid LQ that is used to form the immersion space LS. The supply ports 14 are disposed at prescribed positions of the liquid immersion member 4 in the vicinity of the optical path of the exposure light EL so that they face the optical path. The supply ports 14 are connected to a liquid supply apparatus 17 via passageways 16. The liquid supply apparatus 17 is capable of feeding the liquid LQ, which is pure and temperature adjusted, to the liquid immersion member 4. Each passageway 16 comprises a supply passageway, which is formed inside the liquid immersion member 4, and a passageway, which is formed from a supply pipe that connects the supply passageway and the liquid supply apparatus 17. The liquid LQ that is fed from the liquid supply apparatus 17 is supplied to each of the supply ports 14 through the corresponding passageway 16.

The recovery port 15 is capable of recovering at least part of the liquid LQ on the object that opposes the lower surface 7 of the liquid immersion member 4. In the present embodiment, the recovery port 15 is disposed around the opening 4K, wherethrough the exposure light EL passes. The recovery port 15 is disposed at a prescribed position of the liquid immersion member 4 at which it opposes the front surface of the object. A plate shaped porous member 18, which has a plurality of holes (openings or pores) is disposed in the recovery port 15. Furthermore, a mesh filter, which is a porous member wherein numerous small holes are formed as a mesh, may be disposed in the recovery port 15. In the present embodiment, at least part of the lower surface 7 of the liquid immersion member 4 includes the lower surface of the porous member 18. The recovery port 15 is connected to a liquid recovery apparatus 20 via a passageway 19. The liquid recovery apparatus 20 comprises a vacuum system and is capable of recovering the liquid LQ via suctioning. The passageway 19 comprises a recovery passageway, which is formed inside the liquid immersion member 4, and a passageway, which is formed from a recovery pipe that connects the recovery passageway and the liquid recovery apparatus 20. The liquid LQ recovered via the recovery port 15 is recovered by the liquid recovery apparatus 20 through the passageway 19.

In the present embodiment, the control apparatus 3 is capable of forming the immersion space LS with the liquid LQ between the last optical element 5 and the liquid immersion member 4 on the one side and the object on the other side by performing a liquid recovery operation, wherein the recovery port 15 is used, in parallel with a liquid supply operation, wherein the supply ports 14 are used.

The substrate table 12 comprises a first holding part 23, which has an opening 21 (opening portion) and an upper surface 22, which is used to hold the substrate W inside the opening 21. The first holding part 23 opposes and holds a rear surface (lower surface) Wb of the substrate W. The substrate table 12 has a base material 24. The first holding part 23 is provided to an upper surface 25 of the base material 24, which is capable of opposing the rear surface Wb of the substrate W. In addition, as shown in FIG. 3, the first holding part 23 holds the substrate W so that a center C of the opening 21 substantially coincides with the center of the substrate W.

In the present embodiment, the first holding part 23 comprises a so-called pin chuck mechanism and releasably holds the substrate W. In the present embodiment, the first holding part 23 comprises: a plurality of first support parts 26, which is disposed on the upper surface 25 of the base material 24 and supports the rear surface Wb of the substrate W; a first rim part 27, which is disposed on the upper surface 25 around the first support parts 26 and has an annular upper surface 27T that opposes the rear surface Wb of the substrate W; and first suction ports 28, which are disposed in the upper surface 25 on the inner side of the first rim part 27 and suction a gas. Each of the first support parts 26 has a pin shape (protruding shape).

Each of the first support parts 26 has an upper surface 26T for holding the rear surface Wb of the substrate W. In the present embodiment, each of the upper surfaces 26T is substantially parallel to the XY plane. In addition, each of the upper surfaces 26T is disposed within (flush with) substantially the same plane.

In the present embodiment, the upper surface 22 that is used to hold the substrate W inside the opening 21 includes the upper surfaces 26T of the plurality of first support parts 26. In the explanation below, the upper surface 22 used to hold the substrate W inside the opening 21 is discretionarily called the first holding surface 22. The first holding surface 22 is substantially parallel to the XY plane.

The first rim part 27 is formed in an annular shape that is substantially the same as the external shape of the substrate W. The upper surface 27T of the first rim part 27 opposes a circumferential edge area (edge area) of the rear surface Wb of the substrate W. A plurality of the first suction ports 28 is provided to the upper surface 25 on the inner side of the first rim part 27. Each of the first suction ports 28 is connected to a suction apparatus (not shown), which comprises a vacuum system. The control apparatus 3 chucks the substrate W to the first holding surface 22 by using the suction apparatus to exhaust the gas of a first space—which is enclosed by the rear surface Wb of the substrate W, the first rim part 27, and the base material 24—via the first suction ports 28, thereby negatively pressurizing the first space. In addition, the substrate W can be released from the first holding part 23 by stopping the suction operation performed by the suction apparatus, which is connected to the first suction ports 28.

In addition, in the present embodiment, the substrate table 12 comprises a second holding part 29, which is disposed around the first holding part 23. The second holding part 29 has an upper surface 34 for holding a plate member T around the first holding part 23. The second holding part 29 opposes and holds a rear surface (lower surface) Tb of the plate member T. The second holding part 29 is provided on the upper surface 25 of the base material 24, which is capable of opposing the rear surface Tb of the plate member T.

The plate member T has an opening TH for the purpose of disposing the substrate W therein. A front surface Ta and the rear surface Tb of the plate member T are formed around the opening TH. The plate member T held by the second holding part 29 is disposed around the substrate W, which is held by the first holding part 23.

The second holding part 29 comprises a so-called pin chuck mechanism and releasably holds the plate member T. In the present embodiment, the second holding part 29 comprises: a second rim part 30, which is disposed on the upper surface 25 around the first rim part 27 and has an annular upper surface 30T that opposes the rear surface Tb of the plate member T; a third rim part 31, which is disposed on the upper surface 25 around the second rim part 30 and has an annular upper surface 31T that opposes the rear surface Tb of the plate member T; a plurality of second support parts 32, which is disposed on the upper surface 25 between the second rim part 30 and the third rim part 31 and supports the rear surface Tb of the plate member T; and second suction ports 33, which are disposed in the upper surface 25 between the second rim part 30 and the third rim part 31 and suction a gas. Each of the second support parts 32 has a pin shape (protruding shape).

Each of the second support parts 32 has an upper surface 32T that is used to hold the rear surface Tb of the plate member T. In the present embodiment, each of the upper surfaces 32T is substantially parallel to the XY plane. In addition, each of the upper surfaces 32T is disposed within (flush with) substantially the same plane.

In the present embodiment, the upper surface 34 that is used to hold the plate member T around the first holding part 23 includes the upper surfaces 32T of the plurality of second support parts 32. In the explanation below, the upper surface 34 used to hold the plate member T around the first holding part 23 is discretionarily called the second holding surface 34. The second holding surface 34 is substantially parallel to the XY plane.

The upper surface 30T of the second rim part 30 opposes an inner edge area (an edge area on the inner side) of the rear surface Tb of the plate member T in the vicinity of the opening TH. The upper surface 31T of the third rim part 31 opposes an outer edge area (an edge area on the outer side) of the rear surface Tb of the plate member T. A plurality of the second suction ports 33 is provided in the upper surface 25 between the second rim part 30 and the third rim part 31. Each of the second suction ports 33 is connected to a suction apparatus (not shown), which comprises a vacuum system. The control apparatus 3 chucks the plate member T to the second holding surface 34 by using the suction apparatus to exhaust the gas of a second space—which is enclosed by the rear surface Tb of the plate member T, the second rim part 30, the third rim part 31, and the base material 24—via the second suction ports 33, thereby negatively pressurizing the second space. In addition, the plate member T can be released from the second holding part 29 by stopping the suction operation performed by the suction apparatus, which is connected to the second suction ports 33.

In the present embodiment, the first holding surface 22 and the second holding surface 34 are disposed at substantially the same position (height) with respect to the Z axial directions.

In the present embodiment, the holding of the plate member T by the second holding part 29 forms the opening 21 around the first holding part 23. In the present embodiment, the opening 21 is defined by an edge part Eg on the opening TH side (inner side) of the plate member T. The first holding part 23 holds the substrate W inside the opening 21 (TH) of the plate member T, which is held by the second holding part 29.

In the present embodiment, the first holding part 23 holds the substrate W so that a front surface Wa of the substrate W is substantially parallel to the first holding surface 22 (XY plane). The second holding part 29 holds the plate member T so that the front surface Ta of the plate member T is substantially parallel to the second holding surface 34 (XY plane).

The front surface Wa of the substrate W and the front surface Ta of the plate member T are capable of opposing the emergent surface 6 and the lower surface 7. In the present embodiment, the front surface Ta of the plate member T forms an upper surface of the substrate stage 2 (substrate table 12), which is capable of opposing the emergent surface 6 and the lower surface 7.

In addition, in the present embodiment, the first holding part 23 holds the substrate W so that a side surface Wc of the substrate W and the edge part Eg of the plate member T, which is held by the second holding part 29 and defines the opening 21, oppose one another with a gap G interposed therebetween.

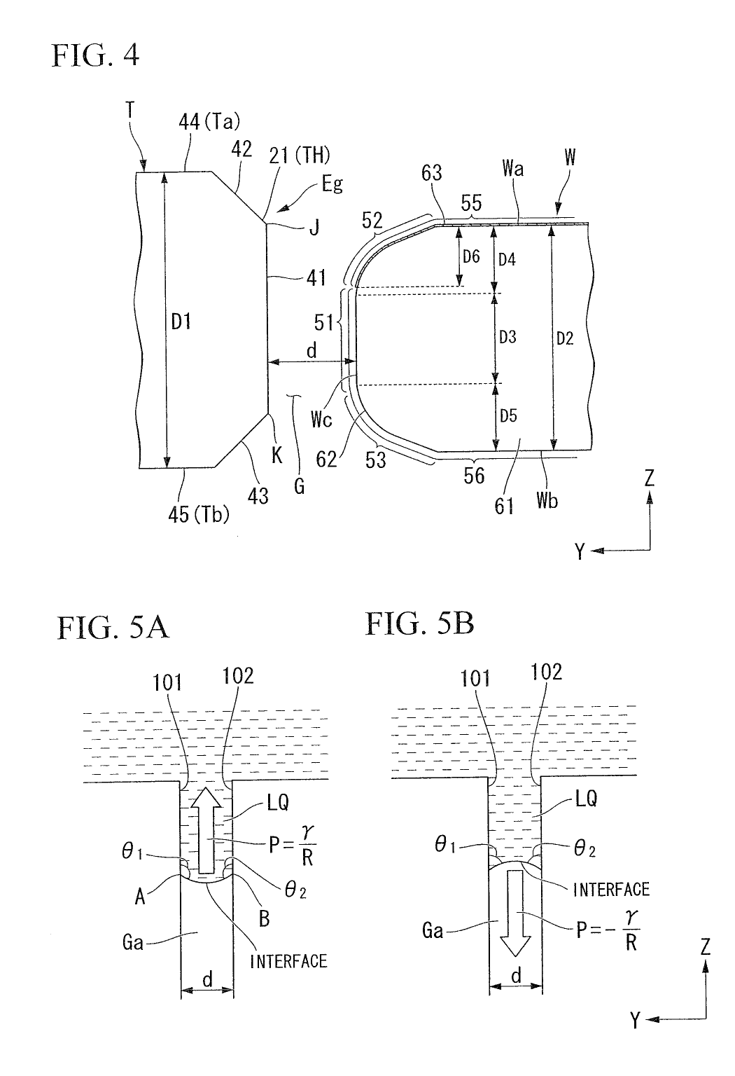

FIG. 4 is an enlarged side cross sectional view (YZ cross sectional view) of the side surface Wc of the substrate W held by the first holding part 23 and the vicinity of the edge part Eg of the plate member T held by the second holding part 29 (a wall adjacent to the substrate W, a wall lateral to the substrate W). The following text explains the state wherein the substrate W is held by the first holding part 23 and the plate member T is held by the second holding part 29.

The edge part Eg of the plate member T that defines the opening 21 has a first surface 41 and a second surface 42, which is provided adjoining the first surface 41. In the present embodiment, the first surface 41 is substantially perpendicular to the first holding surface 22 (XY plane). The first surface 41 is a substantially vertical surface along the thickness direction of the substrate W. The second surface 42 is disposed so that it extends upward (toward the +Z side) from a boundary part J of the first surface 41 and toward the outer side with respect to the center C of the opening 21. Namely, the second surface 42 extends so that the further it is from the boundary part J between the first surface 41 and the second surface 42, the more spaced apart it becomes from the center C of the opening 21. In other words, the second surface (a first gradient surface) 42 has a declination to the substrate W. In the present embodiment, the first surface 41 and the second surface 42 are nonparallel. Furthermore, the opening 21 is substantially circular, and the center C of the opening 21 is the center of this circle. In addition, in the present embodiment, the boundary part J is an angle part (or a corner) at which the first surface 41 and the second surface 42 are connected and comprises an upper end of the first surface 41 and a lower end of the second surface 42. Furthermore, the boundary part J between the first surface 41 and the second surface 42 may be rounded in a cross section (i.e., a round corner) that is parallel to the Z axis and that includes the center C of the opening 21.

In addition, in the present embodiment, the boundary part J between the first surface 41 and the second surface 42 is disposed at a position that is substantially the same height as, or higher than, the front surface Wa of the substrate W held by the first holding part 23. The present embodiment explains an exemplary case wherein the boundary part J between the first surface 41 and the second surface 42 is disposed at substantially the same height as the front surface Wa of the substrate W. Furthermore, the boundary part J between the first surface 41 and the second surface 42 may be disposed at a position that is slightly higher than the front surface Wa of the substrate W, namely slightly on the +Z side of the front surface Wa of the substrate W.

In addition, in the present embodiment, the edge part Eg of the plate member T has a third surface 43, which is formed below (on the −Z side of) the first surface 41 and is nonparallel to the first surface 41. The third surface 43 is provided so that it adjoins the first surface 41. The third surface 43 is disposed so that it extends downward (toward the −Z side) from a boundary part K between the first surface 41 and the third surface 43 and toward the outer side with respect to the center C of the opening 21. Namely, the third surface 43 extends so that the further it is from the boundary part K between the first surface 41 and the third surface 43, the more spaced apart it becomes from the center C of the opening 21. In other words, the third surface (a second gradient surface) 43 has an inclination up to the substrate W. Furthermore, in the present embodiment, the boundary part K is an angle part at which the first surface 41 and the third surface 43 are connected and comprises the lower end of the first surface 41 and the upper end of the third surface 43. Furthermore, the boundary part K between the first surface 41 and the third surface 43 may be rounded in a cross section that is parallel to the Z axis and that includes the center C of the opening 21.

The front surface Ta of the plate member T is provided such that it adjoins the second surface 42 and is disposed so that it extends toward the outer side with respect to the center C of the opening 21. Namely, the front surface Ta extends so that the further it is from a boundary part between the second surface 42 and the front surface Ta, the more spaced apart it becomes from the center C of the opening 21. The front surface Ta of the plate member T is substantially parallel to the first holding surface 22 (the XY plane). In the explanation below, the front surface Ta of the plate member T is discretionarily called the fourth surface 44. The fourth surface 44 is a substantially horizontal surface along a direction orthogonal to the thickness direction of the substrate W. Furthermore, in the present embodiment, the boundary part between the second surface 42 and the fourth surface 44 is an angle part at which the second surface 42 and the fourth surface 44 are connected and comprises the upper end of the second surface 42. Furthermore, the boundary part between the second surface 42 and the fourth surface 44 may be rounded in a cross section that is parallel to the Z axis and that includes the center C of the opening 21.

The rear surface Tb of the plate member T is provided such that it adjoins the third surface 43 and is disposed so that it extends toward the outer side with respect to the center C of the opening 21. Namely, the rear surface Tb extends so that the further it is from a boundary part between the third surface 43 and the rear surface Tb, the more spaced apart it becomes from the center C of the opening 21. The rear surface Tb of the plate member T is substantially parallel to the first holding surface 22 (the XY plane). In the explanation below, the rear surface Tb of the plate member T is discretionarily called the fifth surface 45. Furthermore, in the present embodiment, the boundary part between the third surface 43 and the fifth surface 45 is an angle part at which the third surface 43 and the fifth surface 45 are connected and comprises the lower end of the third surface 43. Furthermore, the boundary part between the third surface 43 and the fifth surface 45 may be rounded in a cross section that is parallel to the Z axis and that includes the center C of the opening 21.

In the present embodiment, the fourth surface 44 and at least part of the second surface 42 of the plate member T, which is held by the second holding part 29, is disposed on the upper side (+Z side) of the front surface Wa of the substrate W, which is held by the first holding part 23.

In the present embodiment, the fourth surface 44 and the fifth surface 45 of the plate member T are substantially parallel. In the present embodiment, a distance D1 (i.e., the thickness of the plate member T) between the fourth surface 44 and the fifth surface 45 of the plate member T is greater than a distance D2 (i.e., the thickness of the substrate W) between the front surface Wa and the rear surface Wb of the substrate W. In the present embodiment, the thickness D2 of the substrate W is approximately 0.775 mm.

The edge part Eg of the plate member T is provided substantially along the side surface Wc of the substrate W, which is held by the first holding part 23 (The edge part Eg is substantially parallel to the side surface Wc of the substrate W). Accordingly, the first surface 41, the second surface 42, and the third surface 43 are provided so that they follow along the side surface Wc of the substrate W, which is held by the first holding part 23. The first holding part 23 holds the substrate W so that the side surface Wc of the substrate W and the first surface 41 of the plate member T oppose one another, with the gap G interposed therebetween. In the present embodiment, a size d of the gap G is, for example, approximately 0.1-0.5 mm.

In the present embodiment, the second surface 42 is formed by a chamfering process. In addition, in the present embodiment, the third surface 43 is also formed by a chamfering process. In the present embodiment, the chamfer angle of the chamfering process is substantially 45°. When various types of members are fabricated from a material like metal, a chamfering process is often performed on the edge part at the time of fabrication. In the present embodiment, a chamfering process is performed on the edge part Eg of the plate member T, which is disposed around the substrate W, and the second surface 42 and the third surface 43 are formed thereby. Performing the chamfering process eliminates burrs on the edge part Eg and prevents the generation of foreign matter.

In the present embodiment, the first surface 41 is liquid repellent or lyophobic with respect to the liquid LQ. In addition, the second surface 42 is liquid repellent with respect to the liquid LQ. In addition, the third surface 43 is also liquid repellent with respect to the liquid LQ. In addition, the fourth surface 44 is also liquid repellent with respect to the liquid LQ. In addition, the fifth surface 45 is also liquid repellent with respect to the liquid LQ.

In the present embodiment, the plate member T comprises a metallic base material (e.g., stainless steel) and a film of a liquid repellent material that is formed on the base material. In the present embodiment, the first through fifth surfaces 41-45 of the plate member T include surfaces of films made of the liquid repellent material. Examples of liquid repellent materials include tetrafluoroethylene-perfluoroalkyl vinyl ether copolymer (PFA), tetrafluoroethylene (PTFE), polyetheretherketone (PEEK), and Teflon™. Thereby, each of the first through fifth surfaces 41-45 is made liquid repellent with respect to the liquid LQ. The contact angle of the liquid LQ with respect to each of the first through fifth surfaces 41-45 is, for example, 90° or greater. In the present embodiment, the base material of the plate member T is stainless steel (SUS316) and the liquid repellent material that forms the film is PFA. In the present embodiment, the contact angle of the liquid LQ with respect to each of the first through fifth surfaces 41-45 is approximately 110°. Furthermore, the plate member T itself may be formed from the liquid repellent material.

The front surface Wa and the rear surface Wb of the substrate W are substantially parallel. The side surface Wc of the substrate W comprises: a perpendicular area 51, which is substantially perpendicular to the front surface Wa of the substrate W; an upper area 52, which links the upper end of the perpendicular area 51 and the front surface Wa of the substrate W; and a lower area 53, which links the lower end of the perpendicular area 51 and the rear surface Wb of the substrate W. In the present embodiment, the cross section of the upper area 52 and the lower area 53 of the side surface Wc of the substrate W comprises a curved surface. The cross section of the perpendicular area 51 is a flat surface.

As discussed above, in the present embodiment, the first holding part 23 holds the substrate W so that the front surface Wa of the substrate W is substantially parallel to the first holding surface 22 (XY plane). Accordingly, the perpendicular area Wc of the substrate W held by the first holding part 23 is substantially perpendicular to the XY plane.

In the present embodiment, a size D4 of the upper area 52 and a size D5 of the lower area 53 in the Z axial directions are each approximately 0.25 mm. The size D4 of the upper area 52 is the distance between the front surface Wa of the substrate W and the lower end of the upper area 52 in the Z axial directions. The size D5 of the lower area 53 is the distance between the rear surface Wb of the substrate W and the upper end of the lower area 53 in the Z axial directions. In the present embodiment, the thickness D2 of the substrate W is approximately 0.775 mm and the size D4 of the upper area 52 and the size D5 of the lower area 53 are each approximately 0.25 mm; therefore, a size D3 of the perpendicular area 51 in the Z axial directions is approximately 0.275 mm.

In the present embodiment, the substrate W comprises: a base material 61 (e.g., a semiconductor wafer, such as a silicon wafer); an HMDS film 62, which is formed on the base material 61; a photosensitive film, which is formed on the HMDS film 62; and a protective film (topcoat film) 63, which covers the photosensitive film. The HMDS film 62 is a film of hexamethyldisilazane (HMDS). The photosensitive film is a film of a photosensitive material (such as a photoresist). Furthermore, the photosensitive film is not shown in FIG. 4. The protective film 63 functions to protect the photosensitive film from the liquid LQ. The protective film 63 is liquid repellent with respect to the liquid LQ.

The protective film 63 forms a liquid repellent area 55 that is liquid repellent with respect to the liquid LQ. In the present embodiment, the protective film 63 forms the front surface Wa and part of the side surface Wc of the substrate W. Accordingly, in the present embodiment, the front surface Wa and the abovementioned part of the side surface Wc of the substrate W constitute the liquid repellent area 55, which is liquid repellent with respect to the liquid LQ.

In the present embodiment, the liquid repellent area 55 of the side surface Wc includes the upper area 52 of the side surface Wc. In the present embodiment, a distance D6 (i.e., the distance between the upper end and lower end of the liquid repellent area 55) between the upper end and the lower end of the protective film 63 in the Z axial directions is approximately 0.2 mm.

In the present embodiment, the rear surface Wb of the substrate W and part of the side surface Wc of the substrate W constitute an area 56 wherein the protective film 63 is not formed. In the present embodiment, the area 56 wherein the protective film 63 is not formed is formed from the HMDS film 62. In the present embodiment, the HMDS film 62 forms the lower area 53, the perpendicular area 51, and part of the upper area 52 of the side surface Wc, as well as the rear surface Wb. In the explanation below, the area 56 that is formed from the HMDS film 62 and is outside of the liquid repellent area 55 is discretionarily called the liquid non-repellent area 56. Accordingly, in the present embodiment, the liquid non-repellent area 56 of the side surface Wc includes the lower area 53, the perpendicular area 51, and part of the upper area 52.

In the present embodiment, the contact angle of the liquid LQ with respect to the liquid repellent area 55 is, for example, 90° or greater. In the present embodiment, TCX091 (brand name) made by Tokyo Ohka Kogyo Co., Ltd. is used as the protective film 63 that forms the liquid repellent area 55, and the contact angle of the liquid LQ with respect to the liquid repellent area 55 (the protective film 63) is approximately 94°. In addition, the contact angle of the liquid LQ with respect to the liquid non-repellent area 56 (the HMDS film 62) is approximately 60°. Furthermore, in the present embodiment, the liquid non-repellent area 56 is formed by the HMDS film 62, and the contact angle of the liquid LQ with respect to the substrate surface under the HMDS film 62 is less than 20°. Accordingly, it can be said that the HMDS film 62 is more liquid repellant than the foundation surface of the HMDS film 62.

The substrate W is formed by processes that include: a process that forms the HMDS film 62 on the base material 61; a process that forms the photosensitive film on the HMDS film 62 by, for example, a spin coating method; a process that forms the protective film 63 on the photosensitive film by, for example, the spin coating method; and an edge rinsing process that removes at least part of the photosensitive film and the protective film 63 formed on the side surface Wc of the substrate W. The edge rinsing process forms the liquid non-repellent area 56 on at least part of the side surface Wc of the substrate W. If the protective film 63 exists on a large portion of the side surface Wc, then there is a strong possibility that, for example, the transport apparatus that transports the substrate W or the housing apparatus that stores the substrate W will become contaminated. The edge rinsing process can prevent contamination of, for example, the transport apparatus that transports the substrate W and the housing apparatus that stores the substrate W by reducing the portion of the side surface Wc on which the protective film 63 exists and by providing the liquid non-repellent area 56 to the side surface Wc.

In the present embodiment, at least part of the first surface 41 of the plate member T is disposed so that it opposes the liquid repellent area 55 of the side surface Wc of the substrate W. In the present embodiment, the first surface 41 opposes both the liquid repellent area 55, on which the protective film 63 is formed, and the liquid non-repellent area 56, from which the protective film 63 has been eliminated. In other words, the first surface 41 opposes the boundary between the protective film 63 and the HMDS film 62.

In the present embodiment, as shown in FIG. 2, there are cases wherein the immersion space LS, which is formed from the liquid LQ via the supply ports 14, is formed so that it spans the front surface Wa of the substrate W and the front surface Ta of the plate member T. Namely, there are cases wherein the immersion space LS is formed over the gap G. According to the present embodiment, it is possible to inhibit the liquid LQ from penetrating, via the gap G, the space on the rear surface Wb side of the substrate W. As a result of performing the analysis explained below, the present inventors found that it is possible to inhibit the penetration of the liquid LQ by disposing the boundary part J between the first surface 41 and the second surface 42 at a position that is substantially the same height as, or higher than, the front surface Wa of the substrate W.

FIG. 5A and FIG. 5B is a schematic drawing that shows the general behavior of the liquid LQ once it has penetrated a gap Ga between a front surface 101 of a first member and a front surface 102 of a second member. In the explanation below, the contact angle of the liquid LQ with respect to the front surface 101 is θ₁, the contact angle of the liquid LQ with respect to the front surface 102 is θ₂, the surface tension of the liquid LQ is γ, and the size of the gap Ga is d.

The following equations define an internal pressure P of the liquid LQ that has penetrated the gap Ga between the front surfaces 101, 102 and a radius of curvature R of the interface of the liquid LQ in the gap Ga.

$$R = \frac{d}{cos {θ}_{1} + cos {θ}_{2}} \\ P = \frac{γ}{R} = \frac{γ ( cos {θ}_{1} + cos {θ}_{2} )}{d} \qquad ( 1 )$$

Furthermore, in equation (1), the effect of gravity is ignored. As shown in equation (1), the radius of curvature R of the interface of the liquid LQ varies in accordance with the conditions of the front surfaces 101, 102. The conditions of the front surfaces 101, 102 include the contact angles θ₁, θ₂ and the size d. In addition, the internal pressure P varies in accordance with the radius of curvature R.

FIGS. 5A and 5B shows a case wherein the front surface 101 and the front surface 102 are each parallel to the Z axis, and the contact angle θ₁ and the contact angle θ₂ are equal. In addition, the contact angles θ₁, θ₂ with respect to the front surfaces 101, 102 shown in FIG. 5A are greater than the contact angles θ₁, θ₂ with respect to the front surfaces 101, 102 shown in FIG. 5B.

As shown in FIG. 5A, the shape of the interface of the liquid LQ in the gap Ga is protruding in the −Z direction (a convex shape with a convex surface facing downwards), and the surface tension of the liquid LQ generates internal pressure P oriented in the +Z direction. This inhibits the movement of the interface of the liquid LQ in the −Z direction, which in turn inhibits further penetration of the liquid LQ into the gap Ga. As shown in FIG. 5B, on the other hand, the shape of the interface of the liquid LQ in the gap Ga is protruding in the +Z direction (a concave shape with a concave surface facing downwards), and capillary action generates internal pressure P oriented in the −Z direction. In this case, the movement of the interface of the liquid LQ in the −Z direction is promoted, which also promotes further penetration of the liquid LQ into the gap Ga.

In the explanation below, the state wherein the interface of the liquid LQ in the gap Ga is protruding in the −Z direction is discretionarily called the inhibited state, and the state wherein it is protruding in the +Z direction is discretionarily called the uninhibited state. Accordingly, when the interface of the liquid LQ is in the inhibited state, the penetration of the liquid LQ is inhibited; furthermore, when the interface of the liquid LQ is in the uninhibited state, the penetration of the liquid LQ is promoted.

Thus, in the case wherein the interface of the liquid LQ is formed in the gap Ga between the front surfaces 101, 102, the shape (radius of curvature) of the interface varies with the conditions of the front surfaces 101, 102 between which that interface is positioned. In other words, in the case wherein the interface of the liquid LQ is formed between the front surface 101 and the front surface 102, the conditions of the front surfaces 101, 102 determine the orientation of the internal pressure P of the liquid LQ, that is, they determine whether the penetration of the liquid LQ is inhibited or promoted.

The front surfaces 101, 102 that have conditions capable of setting the interface of the liquid LQ to the inhibited state can inhibit the penetration of the liquid LQ.

In the explanation below, the interface of the liquid LQ can be set to the inhibited state and prescribed positions A, B on the front surfaces 101, 102, at which the movement of the interface of the liquid LQ in the −Z direction can be inhibited, are discretionarily called inhibiting positions A, B. For example, as shown in FIG. 5(A), if the interface of the liquid LQ is positioned at the inhibiting positions A, B on the front surfaces 101, 102, then the interface transitions to the inhibited state and movement in the −Z direction is inhibited; the penetration of the liquid LQ is thereby also inhibited.

Furthermore, equation (1) applies to the case wherein the front surfaces 101, 102 are parallel to the Z axis, as shown in FIGS. 5A and 5B; however, in the case wherein at least one of the front surfaces 101, 102 is inclined with respect to the Z axis, it is necessary to increase the inclination angle with respect to at least one of the contact angles θ₁, θ₂.

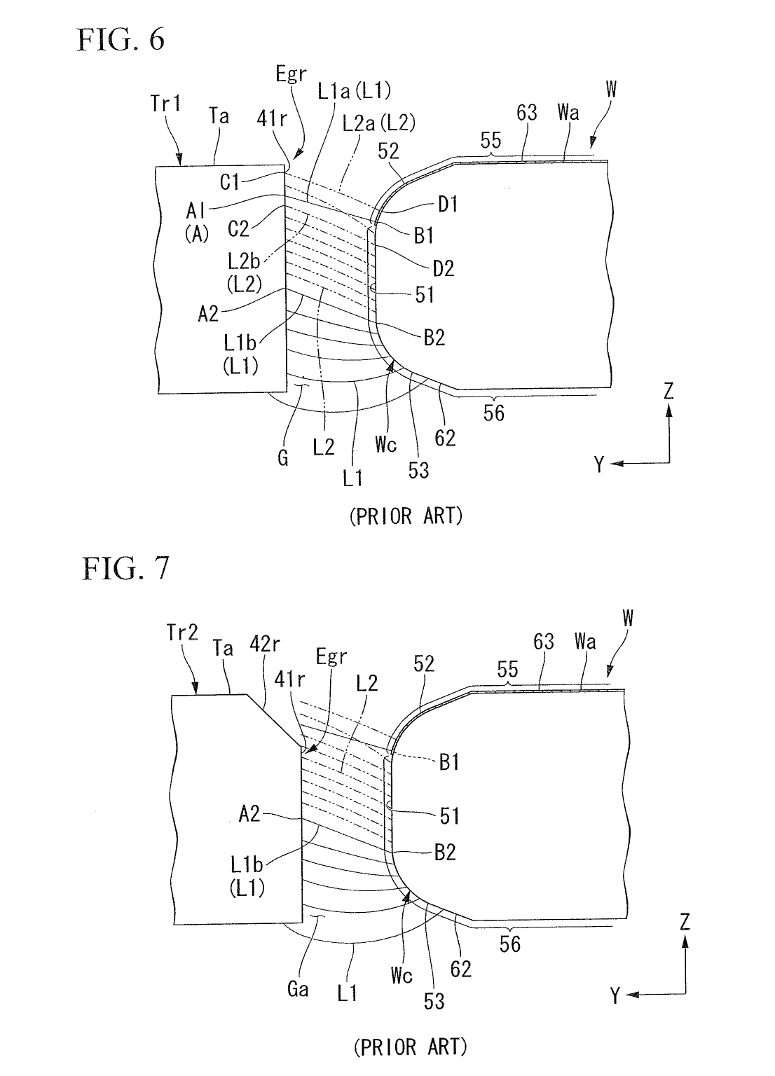

FIG. 6 is a view for explaining the shape of the interface of the liquid LQ formed in the gap Ga between the side surface Wc of the substrate W and an edge part Egr of a plate member Tr1, according to a first comparative example. The substrate W shown in FIG. 6 is identical to the substrate W that was explained referencing FIG. 4. On the other hand, compared with the plate member T according to the present embodiment as shown in FIG. 4 and the like, the plate member Tr1 shown in FIG. 6 does not have the second surface (42) and the third surface (43). Namely, the plate member Tr1 according to the first comparative example does not undergo the chamfering process. In addition, the front surface Ta of the plate member Tr1 and the front surface Wa of the substrate W are at substantially the same height. In addition, the thickness of the plate member Tr1 is substantially the same as that of the substrate W. Accordingly, a first surface 41r of the plate member Tr1 is provided substantially parallel to the Z axis at a position at which it opposes the liquid repellent area 55 of the substrate W. Furthermore, the contact angle of the liquid LQ with respect to the first surface 41r of the plate member Tr1 is approximately 110°.

In a model like the one shown in FIG. 6, the present inventors analyzed, in a manner similar to the analysis performed in FIGS. 5A and 5B, the shape of the interface of the liquid LQ at positions in the Z axial directions between the first surface 41r and the side surface Wc. In FIG. 6, the interface of the liquid LQ in the inhibited state is indicated by a line (solid line) L1, and the interface of the liquid LQ in the uninhibited state is indicated by a line (chain double-dashed line) L2.

In FIG. 6, even in the case wherein the interface of the liquid LQ is formed between a position C1 on the first surface 41r and a position D1 in the upper area 52 of the liquid repellent area 55, as indicated by a line L2a, the interface transitions to the uninhibited state. Namely, even if the interface of the liquid LQ is positioned in the liquid repellent area 55 of the side surface Wc, the inclination angle of the liquid LQ with respect to the Z axis of the side surface Wc at the position D1 is large, and consequently the interface transitions to the uninhibited state.

In FIG. 6, if, as indicated by a line L1a, the interface of the liquid LQ is formed between an inhibiting position A1 on the first surface 41r and an inhibiting position B1 in the upper area 52 of the liquid repellent area 55, then the interface transitions to the inhibited state. Namely, the inclination angle of the liquid LQ with respect to the Z axis of the side surface Wc at the position B1 is relatively small, and consequently the interface of the liquid LQ transitions to the inhibited state. Accordingly, the movement of the interface of the liquid LQ in the −Z direction is inhibited.

In FIG. 6, if, as indicated by a line L2b, the interface of the liquid LQ is formed between a position C2 on the first surface 41r and a position D2 in the perpendicular area 51 of the liquid non-repellent area 56, then the interface transitions to the uninhibited state. Namely, even if the interface of the liquid LQ is positioned in the perpendicular area 51 of the side surface Wc, the contact angle of the liquid LQ with respect to the side surface Wc is not large, and consequently the interface of the liquid LQ transitions to the uninhibited state.

In FIG. 6, the formation of the interface of the liquid LQ between an inhibiting position A2 on the first surface 41r and an inhibiting position B2 in the lower area 53 of the liquid non-repellent area 56, as indicated by a line L1b, causes the interface to transition to the inhibited state. Namely, even if the contact angle of the liquid LQ with respect to the side surface Wc is not large, the interface of the liquid LQ, owing to the inclination of the side surface Wc at the inhibiting position B2, transitions to the inhibited state. As a result, the interface of the liquid LQ is inhibited from moving in the −Z direction.

Thus, in the model shown in FIG. 6, the first surface 41r is provided substantially parallel to the Z axis so that it opposes the liquid repellent area 55 of the side surface Wc at the upper parts of the first surface 41r and the side surface Wc; consequently, it is possible to set the interface of the liquid LQ formed between the first surface 41r and the liquid repellent area 55 of the side surface Wc to the inhibited state and thereby to inhibit the penetration of the liquid LQ. Nonetheless, in the model shown in FIG. 6, although the inhibiting position A (A1) at which the penetration of the liquid LQ can be inhibited exists in the upper part of the first surface 41r, the plate member Tr1 is not chamfered.

FIG. 7 is a view for explaining the shape of the interface of the liquid LQ formed in the gap Ga between the edge part Egr of a plate member Tr2 and the side surface Wc of the substrate W according to a second comparative example. The substrate W shown in FIG. 7 is identical to the substrate W explained referencing FIG. 4. The plate member Tr2 shown in FIG. 7 is fabricated by chamfering the plate member Tr1 shown in FIG. 6 so as to form a second surface 42r.

In the model shown in FIG. 7, the second surface 42r is formed; therefore, unlike the plate member Tr1 in FIG. 6, the inhibiting position A1 that corresponds to the inhibiting position B1 of the side surface Wc does not exist in the plate member Tr2. Namely, because the second surface 42r is formed in the model shown in FIG. 7, the interface of the liquid LQ cannot be formed in the inhibited state either between the first surface 41r and the liquid repellent area 55 of the side surface Wc or between the second surface 42r and the liquid repellent area 55 of the side surface Wc. Accordingly, it is not possible to curb the penetration of the liquid LQ between the side surface Wc and the upper part of the plate member Tr2, and therefore the interface of the liquid LQ tends to move in the −Z direction.

Like the model shown in FIG. 6, the interface of the liquid LQ indicated by the line L1b in FIG. 7 is formed between the inhibiting position A2 on the first surface 41r and the inhibiting position B2 in the lower area 53 of the liquid non-repellent area 56, which makes it possible to inhibit the movement of the interface of the liquid LQ in the −Z direction; however, if the liquid LQ should penetrate as far as this position, then unfortunately there is a greater possibility that the liquid LQ will also penetrate the space on the rear surface Wb side of the substrate W.

In the model shown in FIG. 7, in order to curb the penetration of the liquid LQ to the upper parts of the first surface 41r and the side surface Wc, it is conceivable to, for example, enlarge the liquid repellent area 55 by forming the protective film 63 in part of the perpendicular area 51 of the substrate W as well. Namely, it is conceivable to include in the liquid repellent area 55 the upper part of the perpendicular area 51 that opposes the upper part of the first surface 41r. Nevertheless, as discussed above, if the protective film 63 is formed in the perpendicular area 51 of the side surface Wc of the substrate W, then there is a greater possibility that the transport apparatus that transports the substrate W and the housing apparatus that stores the substrate W will, for example, be contaminated.

In addition, the contact angle of the liquid LQ with respect to the protective film 63 used in the model shown in FIG. 7 is extremely high, which creates the possibility that the penetration of the liquid LQ to the upper parts of the first surface 41r and the side surface Wc can be curbed. Nevertheless, there is a possibility that other problems will occur, such as a narrowing of the range of materials that can be selected for use as the protective film 63.

In addition, it is also conceivable to reduce the amount of chamfer of the plate member Tr2 so as to ensure that the inhibiting position A exists in the upper part of the first surface 41r; however, controlling the amount of chamfer with high precision is problematic and can invite an increase in fabrication cost.

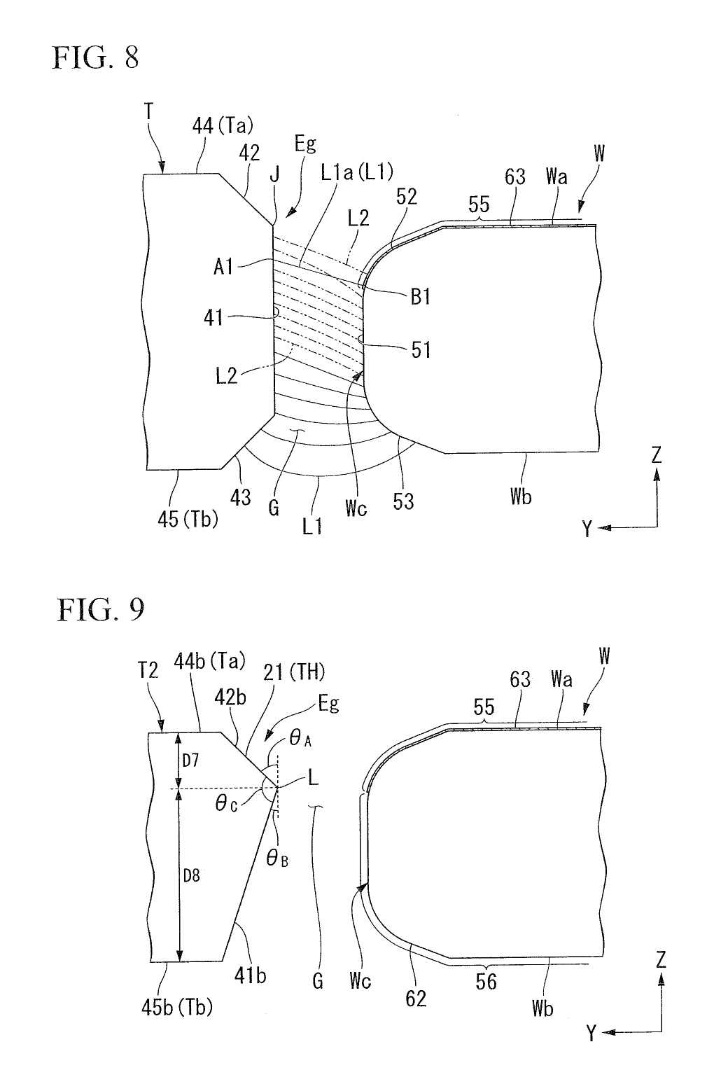

FIG. 8 is a view for explaining the shape of the interface of the liquid LQ formed in the gap G between the edge part Eg of the plate member T and the side surface Wc of the substrate W according to the present embodiment. FIG. 8 shows the results of an analysis of the shape of the interface of the liquid LQ at positions in the Z axial directions between the edge part Eg and the side surface Wc. In FIG. 8, the interface of the liquid LQ in the inhibited state is indicated by the line (solid line) L1, and the interface of the liquid LQ in the uninhibited state is indicated by the line (chain double-dashed line) L2.

As shown in FIG. 8, in the present embodiment, the boundary part J between the first surface 41 and the second surface 42 is disposed at a position that is substantially the same height as or higher than the front surface Wa of the substrate W, which makes it possible to inhibit the penetration of the liquid LQ. Namely, as shown in FIG. 8, it is possible to set the interface of the liquid LQ that is formed between the inhibiting position A1 on the first surface 41 and the inhibiting position B1 in the upper area 52 of the liquid repellent area 55 to the inhibited state, as indicated by the line L1a. Namely, it is possible to set the interface of the liquid LQ formed between the first surface 41 and the liquid repellent area 55 of the side surface Wc to the inhibited state.

Thus, in the present embodiment, the inhibiting position Al exists in the upper part of the first surface 41 and the inhibiting position B2 exists in the upper part of the side surface Wc. Accordingly, it is possible to inhibit the movement of the interface of the liquid LQ in the −Z direction in the upper parts of the first surface 41 and the side surface Wc. Accordingly, it is possible to inhibit the penetration of the liquid LQ via the gap G and thereby to inhibit the liquid LQ from, for example, traveling around to the rear surface Wb side of the substrate W or adhering to the rear surface Wb of the substrate W. In addition, it is possible to inhibit the liquid LQ from traveling around to the rear surface Tb side of the plate member T or adhering to the rear surface Tb of the plate member T.

As explained above, according to the present embodiment, it is possible to inhibit the penetration of the liquid LQ via the gap formed at least partly around the substrate W. Accordingly, it is possible to inhibit, for example, the liquid LQ from penetrating the space on the rear surface Wb side of the substrate W, and so to inhibit the adherence of that liquid LQ to the rear surface Wb of the substrate W. According to the present embodiment, even if the portion at which the protective film 63 exists on the side surface Wc of the substrate W is reduced, it is still possible to inhibit the penetration of the liquid LQ. In other words, it is possible to inhibit the penetration of the liquid LQ even if the side surface Wc of the substrate W includes the liquid non-repellent area 56, wherein the liquid repellent protective film 63 has been removed. Accordingly, it is possible to inhibit the contamination caused by the protective film 63 of the various members and equipment of the exposure apparatus EX (e.g., the transport apparatus and the housing apparatus) as well as external apparatuses (peripheral apparatuses; e.g., a coater and developer apparatus and an etching apparatus). The present invention can thereby additionally prevent exposure failures from occurring and defective devices from being produced.

Furthermore, the thickness of the plate member T may be the same as or less than that of the substrate W. Also in such cases, the height of the second holding surface 34 of the second holding part 29 should be set higher than that of the first holding surface 22 of the first holding part 23 so that the boundary part J between the first surface 41 and the second surface 42 is at substantially the same height as or higher than the front surface of the substrate W.

Furthermore, in the present embodiment, the first surface 41, the second surface 42, and the third surface 43 are formed so that in a cross section they form a straight line that is parallel to the Z axis and that includes the center C of the opening 21, as shown in FIG. 8; however, they may be formed so that they form a curve or a slightly uneven line.

### Second Embodiment

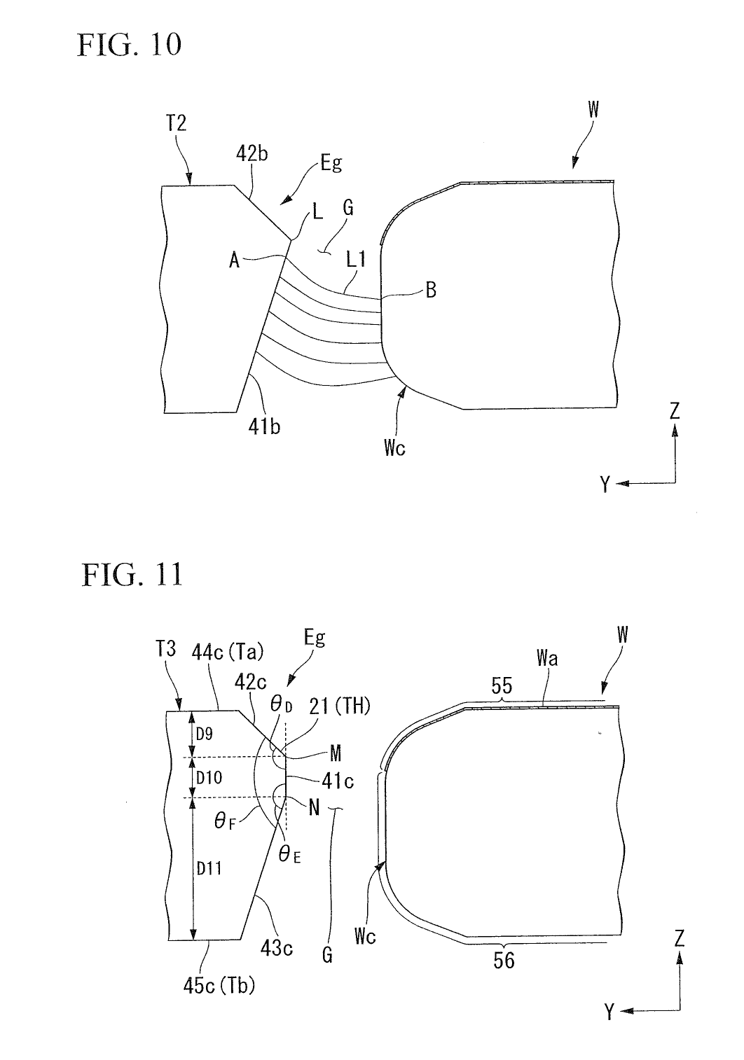

The following text explains a second embodiment, referencing FIG. 9 and FIG. 10. In the explanation below, constituent parts that are identical or equivalent to those in the embodiment discussed above are assigned identical symbols, and the explanations thereof are therefore abbreviated or omitted. The substrate W shown in FIG. 9 and FIG. 10 is identical to the substrate W that was explained referencing FIG. 4.

FIG. 9 is a side cross sectional view (YZ cross sectional view) that shows the vicinity of the edge part Eg of a plate member T2 (an adjacent wall of the substrate W) according to a second embodiment. FIG. 9 shows the state wherein the plate member T2 is held by the second holding part 29 and the substrate W is held by the first holding part 23. Like the embodiment discussed above, the first holding surface 22 of the first holding part 23 is substantially parallel to the XY plane.

In FIG. 9, the edge part Eg (the adjacent wall of the substrate W) of the plate member T2 has a first surface 41b (a first inclined surface part) and a second surface 42b (a second inclined surface part), which is provided adjoining the first surface 41b. The first surface 41b and the second surface 42b are nonparallel.

The second surface 42b is disposed so that it extends both upward (toward the +Z side) from a boundary part L between the first surface 41b and the second surface 42b and toward the outer side with respect to the center C of the opening 21. Namely, the second surface 42b extends so that the further it is from the boundary part L between the first surface 41b and the second surface 42b, the more spaced apart it becomes from the center C of the opening 21. The second surface 42b has a declination to the substrate W. In addition, the first surface 41b is disposed so that it extends from the boundary part L between the first surface 41b and the second surface 42b both downward (toward the −Z side) and toward the outer side with respect to the center C of the opening 21. Namely, the first surface 41b extends so that the further it is from the boundary part L between the first surface 41b and second surface 42b, the more spaced apart it becomes from the center C of the opening 21. The first surface 41b has an inclination up to the substrate W. In addition, in the present embodiment, the boundary part L is an angle part (or a corner) at which the first surface 41b and the second surface 42b are connected and comprises an upper end of the first surface 41b and a lower end of the second surface 42b. The first surface 41b joins together with the second surface 42b at the boundary part L (corner). In the embodiment, the boundary part L is substantially nearest to the substrate W, and located at a height position relatively near to a surface Wa of the substrate W. Furthermore, the boundary part L between the first surface 41b and the second surface 42b may be rounded in a cross section (round corner) that is parallel to the Z axis and that includes the center C of the opening 21.

The edge part Eg of the plate member T2 is provided substantially along the side surface Wc of the substrate W held by the first holding part 23 (The edge part Eg is substantially parallel to the side surface We of the substrate W). Namely, in the present embodiment, the first surface 41b and the second surface 42b are disposed around the substrate W, which is held by the first holding part 23. In the present embodiment, the first holding part 23 holds the substrate W so that the side surface Wc of the substrate W and the first surface 41b (second surface 42b) of the plate member T2 oppose one another with the gap G interposed therebetween.

In the present embodiment, an angle θ_{A} formed between the Z axis and the second surface 42b is larger than an angle θ_{B} formed between the Z axis and the first surface 41b. In addition, in the present embodiment, the first surface 41b is larger than the second surface 42b in the Z axial directions. The size of the second surface 42b in the Z axial directions is indicated by a distance D7 between the boundary part L and a front surface Ta (a fourth surface 44b) of the plate member T2 in the Z axial directions. In addition, the size of the first surface 41b in the Z axial directions is indicated by a distance D8 between the boundary part L and a rear surface Tb (a fifth surface 45b) of the plate member T2 in the Z axial directions. The distance D8 is greater than the distance D7. In addition, in the present embodiment, an angle θ_{C} formed between the first surface 41b and the second surface 42b is 90° or greater. The angle θ_{B} formed between the Z axis and the first surface 41b may be equal to or greater than the angle θ_{A} formed between the Z axis and the second surface 42b.

The plate member T2 has a fourth surface 44b, which is provided such that it adjoins the second surface 42b. The fourth surface 44b is disposed so that it extends from a boundary part between the second surface 42b and the fourth surface 44b toward the outer side with respect to the center C of the opening 21. Namely, the fourth surface 44b extends so that the further it is from the boundary part between the second surface 42b and the fourth surface 44b, the more spaced apart it becomes from the center C of the opening 21. The fourth surface 44b is the front surface Ta of the plate member T2 and is substantially parallel to the first holding surface 22 (the XY plane). Furthermore, in the present embodiment, the boundary part between the second surface 42b and the fourth surface 44b is an angle part at which the second surface 42b and the fourth surface 44b are connected and comprises the upper end of the second surface 42b. Furthermore, the boundary part between the second surface 42b and the fourth surface 44b may be rounded in a cross section that is parallel to the Z axis and that includes the center C of the opening 21.

In addition, the plate member T2 has a fifth surface 45b, which is provided such that it adjoins the first surface 41b. The fifth surface 45b is disposed so that it extends from a boundary part between the first surface 41b and the fifth surface 45b toward the outer side with respect to the center C of the opening 21. Namely, the fifth surface 45b extends so that the further it is from the boundary part between the first surface 41b and the fifth surface 45b, the more spaced apart it becomes from the center C of the opening 21. The fifth surface 45b is the rear surface Tb of the plate member T2 and is substantially parallel to the first holding surface 22 (the XY plane). Furthermore, in the present embodiment, the boundary part between the first surface 41b and the fifth surface 45b is an angle part at which the first surface 41b and the fifth surface 45b are connected and comprises the lower end of the first surface 41b. Furthermore, the boundary part between the first surface 41b and the fifth surface 45b may be rounded in a cross section that is parallel to the Z axis and that includes the center C of the opening 21.

In addition, in the present embodiment, the fourth surface 44b is disposed at substantially the same height as the front surface Wa of the substrate W, which is held by the first holding part 23. In addition, the plate member T2 has substantially the same thickness as the substrate W.

Thus, in the present embodiment, the first surface 41b of the edge part Eg is disposed so that it extends, perpendicular to the fourth surface 44b, from the boundary part L between the first surface 41b and the second surface 42b in the −Z direction and toward the outer side with respect to the center C of the opening 21. The second surface 42b is disposed so that it extends from the boundary part L in the +Z direction and toward the outer side with respect to the center C of the opening 21.

In the present embodiment, the first surface 41b, the second surface 42b, the fourth surface 44b, and the fifth surface 45b are each liquid repellent with respect to the liquid LQ.

In the present embodiment, the boundary part L is disposed so that it opposes the liquid repellent area 55 of the side surface Wc of the substrate W. Accordingly, in the present embodiment, part of the first surface 41b opposes the liquid repellent area 55 formed by the protective film 63. In addition, substantially the entire area of the second surface 42b opposes the liquid repellent area 55 of the side surface Wc. On the other hand, the first surface 41b does not have to oppose the liquid repellent area 55. Namely, the boundary part L between the first surface 41b and the second surface 42b may oppose the perpendicular area 51 of the liquid non-repellent area 56.

In the embodiment, the second surface 42b (a first gradient portion), the first surface 41b (a second gradient portion), and the boundary part L (a corner) form a contour along the thickness direction of the substrate W, that substantially projects toward the substrate W. The contour has a substantially non-symmetrically shape with respect to an axis orthogonal to the thickness direction of the substrate W.

FIG. 10 is a view for explaining the shape of the interface of the liquid LQ formed in the gap G between the edge part Eg of the plate member T2 and the side surface Wc of the substrate W according to the present embodiment FIG. 10 shows the results of the analysis of the shape of the interface of the liquid LQ at positions in the Z axial directions between the edge part Eg and the side surface Wc. In FIG. 10, the interface of the liquid LQ in the inhibited state is indicated by the line (solid line) L1.

As shown in FIG. 10, in the present embodiment, disposing the first surface 41b so that it extends downward from the lower end of the second surface 42b toward the outer side with respect to the center C of the opening 21 makes it possible to inhibit the penetration of the liquid LQ. Namely, in FIG. 10, the interface of the liquid LQ formed between the first surface 41b and the perpendicular area 51 (the liquid non-repellent area 56) of the side surface Wc, as indicated by the line L1, can be set to the inhibited state.

Thus, in the present embodiment, the inhibiting position A exists in the upper part of the first surface 41b and the inhibiting position B exists in the perpendicular area 51 (the liquid non-repellent area 56) of the side surface We. Namely, even if the portion of the side surface Wc of the substrate W at which the protective film 63 exists is reduced, it is still possible to form the interface of the liquid LQ in the inhibited state at a position relatively close to the front surface Wa of the substrate W. Accordingly, it is possible to inhibit the penetration of the liquid LQ via the gap G.

In addition, according to the present embodiment, the angle θ_{C} formed between the first surface 41b and the second surface 42b is 90° or greater. In the present embodiment, the angle θ_{C} formed between the first surface 41b and the second surface 42b is an obtuse angle. Burrs and foreign matter are therefore prevented from being created at the boundary part L between the first surface 41b and the second surface 42b. In addition, the angle formed between the first surface 41b and the fifth surface 45b is 90° or greater (in the present embodiment, an obtuse angle). In addition, the angle formed between the second surface 42b and the fourth surface 44b is 90° or greater (in the present embodiment, an obtuse angle). Burrs and foreign matter are therefore prevented from being created at the boundary part between the first surface 41b and the fifth surface 45b and at the boundary part between the second surface 42b and the fourth surface 44b.

Furthermore, in the present embodiment, the second surface 42b can be formed by a chamfering process.

In addition, in the present embodiment, the first surface 41b and the second surface 42b are formed so that, as shown in FIG. 9 and FIG. 10, they form a straight line in a cross section that is parallel to the Z axis and that includes the center C of the opening 21; however, they may be formed so that they form a curve or a slightly uneven line.

### Third Embodiment

The following text explains a third embodiment, referencing FIG. 11. In the explanation below, constituent parts that are identical or equivalent to those in the embodiments discussed above are assigned identical symbols, and the explanations thereof are therefore abbreviated or omitted. The substrate W shown in FIG. 11 is identical to the substrate W that was explained referencing FIG. 4.

FIG. 11 is a side cross sectional view (YZ cross sectional view) that shows the vicinity of the edge part Eg of a plate member T3 according to a third embodiment. FIG. 11 shows the state wherein the plate member T3 is held by the second holding part 29 and the substrate W is held by the first holding part 23. Like the embodiments discussed above, the first holding surface 22 of the first holding part 23 is substantially parallel to the XY plane.

In FIG. 11, the edge part Eg of the plate member T3 (the adjacent wall of the substrate W) has a first surface 41c (a substantially vertical portion), a second surface 42c (second inclined surface part), and a third surface 43c (first inclined surface part). The second surface 42c is disposed above the first surface 41c. The third surface 43c is disposed below the first surface 41c.

The second surface 42c is provided so that it adjoins the first surface 41c. The third surface 43c is also provided so that it adjoins the first surface 41c. The first surface 41c and the second surface 42c are nonparallel. The first surface 41c and the third surface 43c are also nonparallel. In addition, the second surface 42c and the third surface 43c are nonparallel.

The second surface 42c is disposed so that it extends from a boundary part M between the first surface 41c and the second surface 42c both upward (toward the +Z side) and toward the outer side with respect to the center C of the opening 21. Namely, the second surface 42c extends so that the further it is from the boundary part M between the first surface 41c and the second surface 42c, the more spaced apart it becomes from the center C of the opening 21. The second surface 42c has a declination to the substrate W. The third surface 43c is disposed so that it extends from a boundary part N between the first surface 41c and the third surface 43c both downward (toward the −Z side) and toward the outer side with respect to the center C of the opening 21. Namely, the third surface 43c extends so that the further it is from the boundary part N between the first surface 41c and the third surface 43c, the more spaced apart it becomes from the center C of the opening 21. The third surface 43c has a inclination up to the substrate W. Furthermore, in the present embodiment, the boundary part M is an angle part (or a corner) at which the first surface 41c and the second surface 42c are connected and comprises an upper end of the first surface 41c and a lower end of the second surface 42c. In addition, the boundary part M between the first surface 41c and the second surface 42c may be rounded in a cross section (a round corner) that is parallel to the Z axis and that includes the center C of the opening 21. In addition, in the present embodiment, the boundary part N is an angle part at which the first surface 41c and the third surface 43c are connected, and includes the lower end of the first surface 41c and the upper end of the third surface 43c. The first surface 41c joins together with the second surface 42c at the boundary part M (corner). In the embodiment, the boundary part M is substantially nearest to the substrate W, and located at a height position relatively near to the surface Wa of the substrate W. In addition, the boundary part N between the first surface 41c and the third surface 43c may be rounded in a cross section that is parallel to the Z axis and that includes the center C of the opening 21.

In the present embodiment, the first surface 41c is substantially perpendicular to the first holding surface 22 (XY plane). The first surface 41c (a substantially vertical portion) is located between the second surface 42c and the third surface 43c, and is along the thickness direction of the substrate W. The edge part Eg of the plate member T3 is provided substantially along the side surface Wc of the substrate W held by the first holding part 23 (The edge part Eg is substantially parallel to the side surface Wc of the substrate W). The first holding part 23 holds the substrate W so that the side surface Wc of the substrate W and the edge part Eg of the plate member T3 oppose one another with the gap G interposed therebetween. Namely, the first surface 41c, the second surface 42c, and the third surface 43c are disposed around the substrate W, which is held by the first holding part 23.

In the present embodiment, an angle θ_{D} formed between the Z axis and the second surface 42c is greater than an angle θ_{E} formed between the Z axis and the third surface 43c. In addition, an angle θ_{F} formed between the second surface 42c and the third surface 43c is 90° or greater. In addition, in the present embodiment, the angle θ_{D} formed between the first surface 41c (Z axis) and the second surface 42c is 90° or greater. The angle θ_{E} formed between the first surface 41c (Z axis) and the third surface 43c is also 90° or greater. Furthermore, the angle θ_{E} formed between the Z axis and the first surface 41c may be equal to or greater than the angle θ_{D} formed between the Z axis and the second surface 42c.

In addition, in the present embodiment, the third surface 43c is larger than the first surface 41c in the Z axial directions. In addition, in the present embodiment, the third surface 43c is larger than the second surface 42c in the Z axial directions. The size of the second surface 42c in the Z axial directions is indicated by a distance D9 between the lower end of the second surface 42c and a front surface Ta (a fourth surface 44c) of the plate member T3 in the Z axial directions. In addition, the size of the first surface 41c in the Z axial directions is indicated by a distance D10 between the upper and lower ends of the first surface 41c in the Z axial directions. In addition, the size of the third surface 43c in the Z axial directions is a distance D11 between the lower end of the first surface 41c and a rear surface Tb (a fifth surface 45c) of the plate member T3. In the present embodiment, the distance D11 is greater than the distance D10. In addition, the distance D11 is greater than the distance D9. In addition, the distance D11 is greater than the sum of the distance D9 and the distance D10.

The plate member T3 has a fourth surface 44c, which is provided such that it adjoins the second surface 42c. The fourth surface 44c is disposed so that it extends from a boundary part between the second surface 42c and the fourth surface 44c toward the outer side with respect to the center C of the opening 21. The fourth surface 44c is the front surface Ta of the plate member T3 and is substantially parallel to the first holding surface 22 (the XY plane). Furthermore, in the present embodiment, the boundary part between the second surface 42c and the fourth surface 44c is an angle part at which the second surface 42c and the fourth surface 44c are connected and comprises the upper end of the second surface 42c. Furthermore, the boundary part between the second surface 42c and the fourth surface 44c may be rounded in a cross section that is parallel to the Z axis and that includes the center C of the opening 21.

In addition, the plate member T3 has a fifth surface 45c, which is provided such that it adjoins the third surface 43c. The fifth surface 45c is disposed so that it extends from a boundary part between the third surface 43c and the fifth surface 45c toward the outer side with respect to the center C of the opening 21. The fifth surface 45c is the rear surface Tb of the plate member T3 and is substantially parallel to the first holding surface 22 (the XY plane). Furthermore, in the present embodiment, the boundary part between the third surface 43c and the fifth surface 45c is an angle part at which the third surface 43c and the fifth surface 45c are connected and comprises the lower end of the third surface 43c. Furthermore, the boundary part between the third surface 43c and the fifth surface 45c may be rounded in a cross section that is parallel to the Z axis and that includes the center C of the opening 21.

In addition, in the present embodiment, the fourth surface 44c is disposed at substantially the same height as the front surface Wa of the substrate W, which is held by the first holding part 23.

In the present embodiment, the first surface 41c, the second surface 42c, the third surface 43c, the fourth surface 44c, and the fifth surface 45c are each liquid repellent with respect to the liquid LQ.

In addition, in the present embodiment, part of the first surface 41c opposes the liquid repellent area 55 formed by the protective film 63. In addition, substantially the entire area of the second surface 42c opposes the liquid repellent area 55.

In the embodiment, the second surface 42c (a first gradient portion), the first surface 41c (a substantially vertical portion), the third surface 43c (a second gradient portion), and the boundary part M (a corner) form a contour along the thickness direction of the substrate W, that substantially projects toward the substrate W. The contour has a substantially non-symmetrically shape with respect to an axis orthogonal to the thickness direction of the substrate W.

In the present embodiment, too, the third surface 43c is disposed so that it extends from the lower end of the first surface 41c both downward and toward the outer side with respect to the center C of the opening 21; furthermore, the size (distance D11) of the third surface 43c in the Z directions is greater than the size (distance D9) of the second surface 42c and the size (distance D10) of the first surface 41c; therefore, it is possible to inhibit the penetration of the liquid LQ. Namely, the interface of the liquid LQ formed between the first surface 41c and the upper part of the perpendicular area 51 (the liquid non-repellent area 56) can be set to the inhibited state.

In the present embodiment, too, the inhibiting position exists in the perpendicular area 51 (the liquid non-repellent area 56) of the side surface Wc. Namely, even if the portion of the side surface Wc of the substrate W at which the protective film 63 exists is reduced, it is still possible to form the interface of the liquid LQ in the inhibited state at a position relatively close to the front surface Wa of the substrate W. Accordingly, it is possible to inhibit the penetration of the liquid LQ via the gap G formed at least partly around the substrate W.

In addition, according to the present embodiment, the angle θ_{D} formed between the first surface 41c and the second surface 42c is 90° or greater (in the present embodiment, an obtuse angle). In addition, the angle θ_{E} formed between the first surface 41c and the third surface 43c is 90° or greater (in the present embodiment, an obtuse angle). In addition, the angle formed between the second surface 42c and the fourth surface 44c is 90° or greater (in the present embodiment, an obtuse angle). In addition, the angle formed between the third surface 43c and the fifth surface 45c is 90° or greater (in the present embodiment, an obtuse angle).

Furthermore, in the present embodiment, the second surface 42c can be formed by a chamfering process.

Furthermore, in the present embodiment, the first surface 41c may be nonperpendicular to the first holding surface 22 (XY plane). In this case, the first surface 41c is preferably formed so that it is spaced apart from the center C of the opening 21 and downward from the boundary part M between the first surface 41c and the second surface 42c.

Furthermore, in the present embodiment, the thickness of the plate member T3 may be different from that of the substrate W. In this case, the heights of the first holding surface 22 of the first holding part 23 and the second holding surface 34 of the second holding part 29 may be set differently so that the front surface Ta (the fourth surface 44c) of the plate member T3 and the front surface Wa of the substrate W are at substantially the same height.

In addition, in the present embodiment, to bring the Z directions position of the boundary part N between the first surface 41c and the third surface 43c close to the front surface Wa of the substrate W, the plate member T3 may be held so that the front surface Ta (the fourth surface 44c) of the plate member T3 is higher than the front surface Wa of the substrate W. In this case, the plate member T3 may be made thicker than the substrate W or the second holding surface 34 of the second holding part 29 may be set higher than the first holding surface 22 of the first holding part 23, or both.

In addition, in the present embodiment, the first surface 41c, the second surface 42c, and the third surface 43c are formed so that, as shown in FIG. 11, they form a straight line in a cross section that is parallel to the Z axis and that includes the center C of the opening 21; however, they may alternatively be formed so that they form a curve or a slightly uneven line.

### Fourth Embodiment

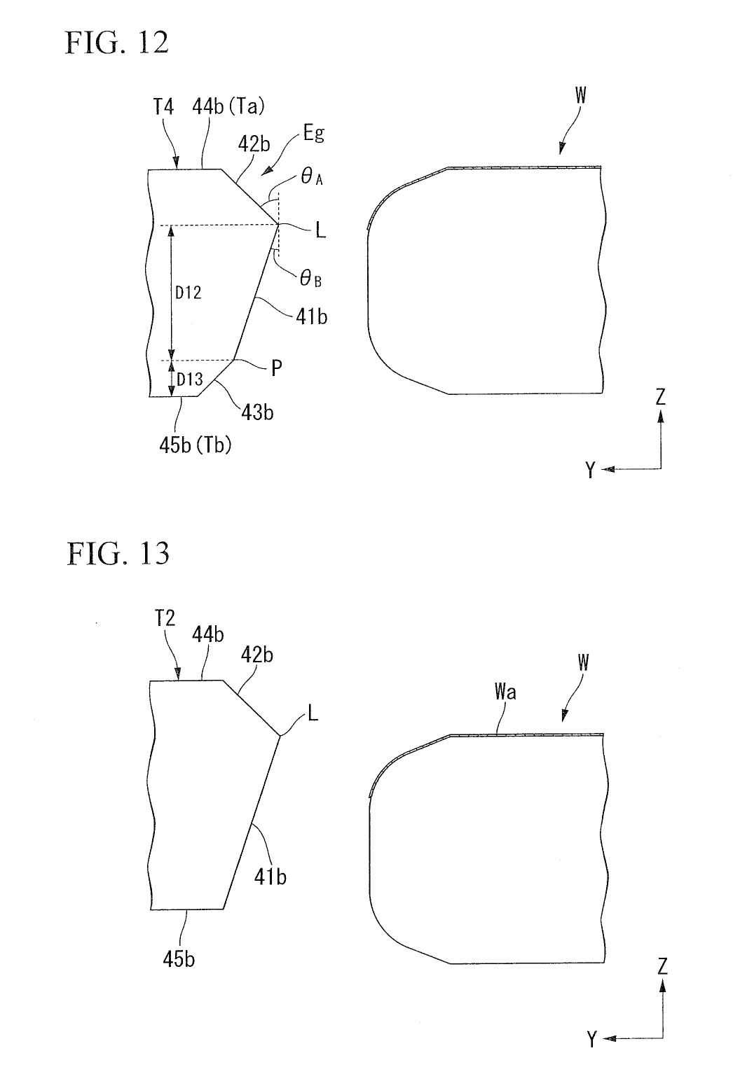

The following text explains a fourth embodiment, referencing FIG. 12. In the explanation below, constituent parts that are identical or equivalent to those in the embodiments discussed above are assigned identical symbols, and the explanations thereof are therefore abbreviated or omitted. The substrate W shown in FIG. 12 is identical to the substrate W that was explained referencing FIG. 4. A plate member T4 according to the fourth embodiment is a modified example of the plate member T2 according to the second embodiment shown in FIG. 9 and the like and differs from the plate member T2 in the second embodiment discussed above in that a third surface 43b is formed below the first surface 41b.

FIG. 12 is a side cross sectional view (YZ cross sectional view) that shows the vicinity of the edge part Eg of the plate member T4 according to the fourth embodiment. As shown in FIG. 12, the edge part Eg of the plate member T4 has the first surface 41b (first inclined surface part) and the second surface 42b (second inclined surface part), which is disposed above the first surface 41b. In the present embodiment, the edge part Eg also has the third surface 43b, which is disposed below the first surface 41b. The first surface 41b and the second surface 42b are nonparallel. The first surface 41b and the third surface 43b are also nonparallel.

The second surface 42b is disposed so that it extends from a boundary part L between the first surface 41b and the second surface 42b both upward (toward the +Z side) and toward the outer side with respect to the center C of the opening 21. The first surface 41b is disposed so that it extends from the boundary part L between the first surface 41b and the second surface 42b both downward (toward the −Z side) and toward the outer side with respect to the center C of the opening 21. The third surface 43b is disposed so that it extends from a boundary part P between the first surface 41b and the third surface 43b both downward (toward the −Z side) and toward the outer side with respect to the center C of the opening 21. Namely, the third surface 43b extends so that the further it is from the boundary part P between the first surface 41b and the third surface 43b, the more spaced apart it becomes from the center C of the opening 21. Furthermore, in the present embodiment, the boundary part L is an angle part at which the first surface 41b and the second surface 42b are connected and comprises an upper end of the first surface 41b and a lower end of the second surface 42b. Furthermore, the boundary part L between the first surface 41b and the second surface 42b may be rounded in a cross section that is parallel to the Z axis and that includes the center C of the opening 21. The boundary part P is an angle part at which the first surface 41b and the third surface 43b are connected and comprises the lower end of the first surface 41b and the upper end of the third surface 43b. Furthermore, the boundary part P between the first surface 41b and the third surface 43b may be rounded in a cross section that is parallel to the Z axis and that includes the center C of the opening 21.

In addition, the first surface 41b is larger than the third surface 43b in the Z axial directions. The size of the first surface 41b in the Z axial directions is a distance D12 between the boundary part L and the boundary part P in the Z axial directions; furthermore, the size of the third surface 43b in the Z axial directions is a distance D13 between the rear surface Tb (the fifth surface 45b) of the plate member T4 and the boundary part P between the first surface 41b and the third surface 43b in the Z axial directions.

In addition, the plate member T4 has a fourth surface 44b, which is provided such that it adjoins the second surface 42b. The fourth surface 44b is disposed so that it extends from the boundary part between the second surface 42b and the fourth surface 44b toward the outer side with respect to the center C of the opening 21. The fourth surface 44b is the front surface Ta of the plate member T4 and is substantially parallel to the first holding surface 22 (the XY plane). In addition, the plate member T4 has the fifth surface 45b, which is provided adjoining the third surface 43b. The fifth surface 45b extends from a boundary part between the third surface 43b and the fifth surface 45b toward the outer side with respect to the center C of the opening 21. The fifth surface 45b is the rear surface Tb of the plate member T4 and is substantially parallel to the first holding surface 22 (the XY plane).

In addition, in the present embodiment, the angle θ_{B} formed between the Z axis and the first surface 41b may be equal to or greater than the angle θ_{A} formed between the Z axis and the second surface 42b.

In the present embodiment, too, the interface of the liquid LQ formed between the first surface 41b and the upper part of the perpendicular area 51 (the liquid non-repellent area 56) of the side surface Wc can be set to the inhibited state and thereby the penetration of the liquid LQ can be inhibited. Furthermore, in the present embodiment, the third surface 43b can be formed by a chamfering process. In addition, in the present embodiment, the first surface 41b, the second surface 42b, and the third surface 43b are formed so that, as shown in FIG. 12, they form a straight line in a cross section that is parallel to the Z axis and that includes the center C of the opening 21; however, they may alternatively be formed so that they form a curve or a slightly uneven line.

### Fifth Embodiment

The following text explains a fifth embodiment, referencing FIG. 13. In the explanation below, constituent parts that are identical or equivalent to those in the embodiments discussed above are assigned identical symbols, and the explanations thereof are therefore abbreviated or omitted. The substrate W shown in FIG. 13 is identical to the substrate W that was explained referencing FIG. 4.

The fifth embodiment is a modified example of the second embodiment discussed above. As shown in FIG. 13, the fourth surface 44b of the plate member T2 according to the second embodiment is disposed at a position that is higher than the front surface Wa of the substrate W held by the first holding part 23. The second surface 41a (a first gradient surface) has a declination to the substrate W, the first surface 41b (a second gradient surface) has a inclination up to the substrate W. The first surface 41b joins together with the second surface 42b at the boundary part L (at a corner). In the example shown in FIG. 13, the boundary part L between the first surface 41b and the second surface 42b is disposed at a position at which it is substantially the same height as or higher than the front surface Wa of the substrate W held by the first holding part 23.

In the present embodiment, too, the interface of the liquid LQ can be set to the inhibited state not only when it is formed between the first surface 41b and the liquid repellent area 55 of the side surface Wc of the substrate W, but also when it is formed between the first surface 41b and the perpendicular area 51 (the liquid non-repellent area 56) of the side surface Wc, thereby making it possible to inhibit the penetration of the liquid LQ.

Furthermore, in the present embodiment, the thickness of the plate member T2 may be different from that of the substrate W. In this case, the height of the second holding surface 34 of the second holding part 29 may be the same as or different from that of the first holding surface 22 of the first holding part 23. In addition, the third surface 43b may exist below the first surface 41b, as in the fourth embodiment.

### Sixth Embodiment

The following explains a sixth embodiment. In the explanation below, constituent parts that are identical or equivalent to those in the embodiments discussed above are assigned identical symbols, and the explanations thereof are therefore abbreviated or omitted.

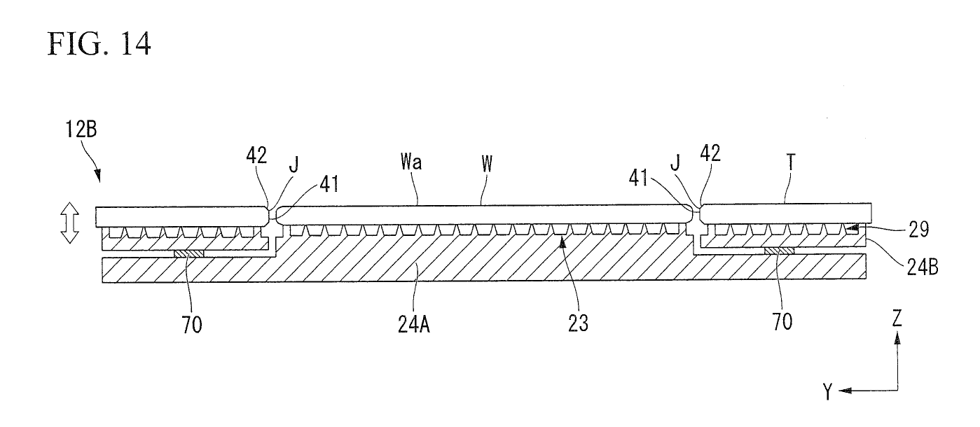

FIG. 14 is a side cross sectional view that shows one example of a substrate table 12B according to the sixth embodiment. In FIG. 14, the substrate table 12B comprises a first base material 24A, whereon the first holding part 23 is formed, and a second base material 24B, whereon the second holding part 29 is formed. The first holding part 23 releasably holds the substrate W. The second holding part 29 releasably holds the plate member T.

In the present embodiment, the second base material 24B is capable of moving with respect to the first base material 24A. In the present embodiment, drive systems 70, each of which comprises, for example, an actuator such as a voice coil motor, are disposed between the first base material 24A and the second base material 24B. The second base material 24B is capable of moving with respect to the first base material 24A by the operation of the drive systems 70. The movement of the second base material 24B with respect to the first base material 24A moves the plate member T, which is held by the second holding part 29 of the second base material 24B, with respect to the substrate W, which is held by the first holding part 23 of the first base material 24A. In the present embodiment, the plate member T is capable of moving in at least the Z axial directions by the operation of the drive systems 70.

The control apparatus 3 can adjust the positional relationship between the substrate W, which is held by the first holding part 23, and the plate member T, which is held by the second holding part 29, by controlling the drive systems 70. For example, if the plate member T explained in the first embodiment discussed above is held by the second holding part 29, then the control apparatus 3 can adjust the position of the boundary part J between the first surface 41 and the second surface 42 of the plate member T in the Z axial directions with respect to the front surface Wa of the substrate W by controlling the drive systems 70. Accordingly, even if the thickness of the plate member T is substantially the same as that of the substrate W, the control apparatus 3 can, for example, dispose the boundary part J of the plate member T at substantially the same height as or higher than the front surface Wa of the substrate W, which is held by the first holding part 23, by the operation of the drive systems 70.

Thus, the substrate table 12B of the present embodiment can hold the plate member T so that the boundary part J thereof is disposed at a position that is substantially the same height as or higher than the front surface Wa of the substrate W held by the first holding part 23. In the present embodiment, too, the penetration of the liquid LQ can be inhibited.

Furthermore, any one plate member of the plate members T2, T3, T4 may be held by the second holding part 29 of the present embodiment.

Furthermore, in the first through sixth embodiments discussed above, the opening 21 is defined by a single plate member; however, a plurality of plate members may be held and the opening 21 may be defined thereby.

### Seventh Embodiment

The following text explains a seventh embodiment. In the explanation below, constituent parts that are identical or equivalent to those in the embodiments discussed above are assigned identical symbols, and the explanations thereof are therefore abbreviated or omitted.

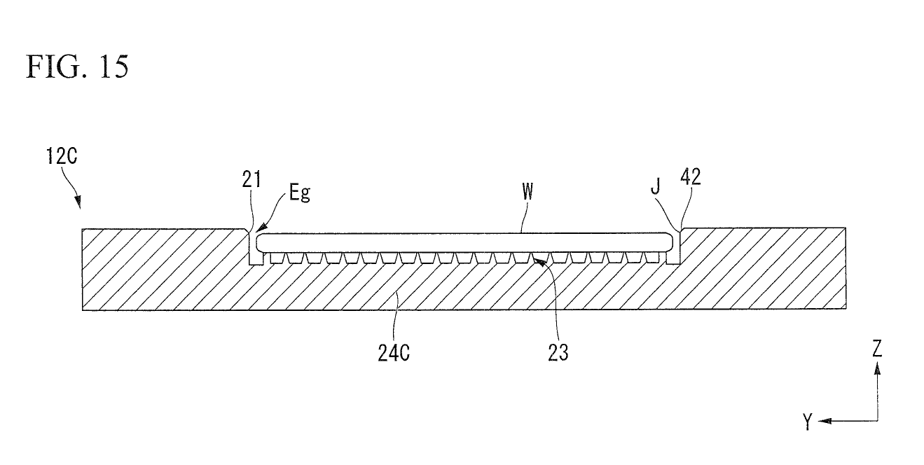

FIG. 15 is a side cross sectional view that shows one example of a substrate table 12C according to the seventh embodiment. The first through sixth embodiments discussed above explained an exemplary case wherein the edge part Eg, which defines the opening 21 wherein the first holding part 23 is disposed, is provided to the plate member T (T2-T4); however, as shown in FIG. 15, the edge part Eg that defines the opening 21 may be part of the substrate table 12C (a base material 24C). In this case, too, at least one of the first surface (41, 41b, 41c), the second surface (42, 42b, 42c), and the third surface (43, 43b, 43c) should be provided to the substrate table 12C, as with the plate members T, T2, T3, T4 discussed above.

In addition, in the first through seventh embodiments discussed above, the opening 21 is circular, but it need not be so. For example, the substrate W may be a rectangle, in which case the opening 21 should be rectangular.

Furthermore, in the first through seventh embodiments discussed above, the liquid repellent area 55 of the substrate W is formed by the protective film 63; however, if the photosensitive film of the substrate W is liquid repellent with respect to the liquid LQ, then the protective film 63 may be omitted. In this case, the front surface Wa of the substrate W includes the front surface of the photosensitive film. In addition, at least part of the upper area 52 of the side surface Wc of the substrate W may be formed from a liquid repellent photosensitive film.

In addition, the first through seventh embodiments discussed above explained a case wherein the substrate W has a diameter of 300 mm (a thickness of 0.775 mm); however, each of the embodiments can also be adapted to a substrate W with a diameter of 200 mm or 450 mm.

In addition, in the first through seventh embodiments discussed above, the optical path on the emergent side (image plane side) of the last optical element 5 of the projection optical system PL is filled with the liquid LQ; however, it is possible to use a projection optical system PL wherein the optical path on the incident side (object plane side) of the last optical element 5 is also filled with the liquid LQ as disclosed in, for example, PCT International Publication WO 2004/019128.

Furthermore, in each of the embodiments discussed above, water is used as the liquid LQ, but a liquid other than water may be used. For example, it is also possible to use hydro-fluoro-ether (HFE), perfluorinated polyether (PFPE), Fomblin oil, or the like as the liquid LQ.

Furthermore, the substrate W in each of the embodiments discussed above is not limited to a semiconductor wafer for fabricating semiconductor devices, but can also be adapted to, for example, a glass substrate for display devices, a ceramic wafer for thin film magnetic heads, or the original plate of a mask or a reticle (synthetic quartz or a silicon wafer) used by an exposure apparatus.

The exposure apparatus EX can also be adapted to a step-and-scan type scanning exposure apparatus (a scanning stepper) that scans and exposes the pattern of the mask MK by synchronously moving the mask MK and the substrate W, as well as to a step-and-repeat type projection exposure apparatus (a stepper) that exposes the substrate W with the full field of the pattern of the mask MK with the mask MK and the substrate W in a stationary state, and then steps the substrate W.

Furthermore, when performing an exposure with a step-and-repeat system, the projection optical system is used to transfer a reduced image of a first pattern onto the substrate W in a state wherein the first pattern and the substrate W are substantially stationary, after which the projection optical system may be used to perform full-field exposure of the substrate W, wherein a reduced image of a second pattern partially superposes the transferred first pattern in a state wherein the second pattern and the substrate W are substantially stationary (as in a stitching type full-field exposure apparatus). In addition, the stitching type exposure apparatus can also be adapted to a step-and-stitch type exposure apparatus that transfers at least two patterns onto the substrate W so that they are partially superposed, and then steps the substrate W.

In addition, the present invention can also be adapted to, for example, an exposure apparatus that combines on a substrate the patterns of two masks through a projection optical system and double exposes, substantially simultaneously, a single shot region on the substrate using a single scanning exposure, as disclosed in, for example, U.S. Pat. No. 6,611,316. In addition, the present invention can also be adapted to, for example, a proximity type exposure apparatus and a mirror projection aligner.

In addition, the present invention can also be adapted to a twin stage type exposure apparatus, which comprises a plurality of substrate stages, as disclosed in, for example, U.S. Pat. Nos. 6,341,007, 6,208,407, and 6,262,796.

Furthermore, as disclosed in, for example, U.S. Pat. No. 6,897,963, the present invention can also be adapted to an exposure apparatus that is provided with: a substrate stage, which holds the substrate; and a measurement stage that does not hold the substrate to be exposed and whereon a fiducial member, wherein a fiducial mark is formed, and/or various photoelectric sensors are mounted. In addition, the present invention can also be adapted to an exposure apparatus that comprises a plurality of substrate stages and measurement stages.

The type of exposure apparatus EX is not limited to a semiconductor device fabrication exposure apparatus that exposes the substrate W with the pattern of a semiconductor device, but can also be widely adapted to exposure apparatuses used for fabricating, for example, liquid crystal devices or displays and to exposure apparatuses used for fabricating thin film magnetic heads, image capturing devices (CCDs), micromachines, MEMS devices, DNA chips, or reticles and masks.

Furthermore, in each of the embodiments discussed above, the positions of the mask stage 1 and the substrate stage 2 are measured using an interferometer system that comprises laser interferometers, but the present invention is not limited thereto; for example, an encoder system may be used that detects a scale (diffraction grating) provided to each of the stages 1, 2. In this case, a hybrid system that comprises both the interferometer system and the encoder system may be adopted.

In addition, in each of the embodiments discussed above, an ArF excimer laser may be used as a light source apparatus that generates ArF excimer laser light, which serves as the exposure light EL; however, as disclosed in, for example, U.S. Pat. No. 7,023,610, a harmonic generation apparatus may be used that outputs pulsed light with a wavelength of 193 nm and that comprises: an optical amplifier part, which has a solid state laser light source (such as a DFB semiconductor laser or a fiber laser), a fiber amplifier, and the like; and a wavelength converting part. Moreover, in the abovementioned embodiments, both the illumination area and the projection area are rectangular, but they may be some other shape, for example, arcuate.

Furthermore, in each of the embodiments discussed above, an optically transparent type mask is used wherein a prescribed shielding pattern (or phase pattern or dimming pattern) is formed on an optically transparent substrate; however, instead of such a mask, a variable pattern forming mask (also called an electronic mask, an active mask, or an image generator), wherein a transmissive pattern, a reflective pattern, or a light emitting pattern is formed based on electronic data of the pattern to be exposed, may be used as disclosed in, for example, U.S. Pat. No. 6,778,257. The variable pattern forming mask comprises a digital micromirror device (DMD), which is one kind of non-emissive type image display device (spatial light modulator). In addition, instead of a variable pattern forming mask provided with a non-emissive type image display device, a pattern forming apparatus that comprises a self luminous type image display device may be provided. Examples of a self luminous type image display device include a cathode ray tube (CRT), an inorganic electroluminescence display, an organic electroluminescence display (OLED: organic light emitting diode), an LED display, an LD display, a field emission display (FED), and a plasma display (PDP: plasma display panel).

Each of the embodiments discussed above explained an exemplary case of an exposure apparatus that is provided with the projection optical system PL, but the present invention can be adapted to an exposure apparatus and an exposing method that do not use the projection optical system PL. Thus, even if the projection optical system PL is not used, the exposure light can be radiated onto the substrate through optical members, for example, lenses, and an immersion space can be formed in a prescribed space between the substrate and those optical members.

In addition, by forming interference fringes on the substrate W as disclosed in, for example, PCT International Publication WO2001/035168, the present invention can also be adapted to an exposure apparatus (a lithographic system) that exposes the substrate W with a line-and-space pattern.

As described above, the exposure apparatus EX of the present embodiment is manufactured by assembling various subsystems, including each constituent element recited, so that prescribed mechanical, electrical, and optical accuracies are maintained. To ensure these various accuracies, adjustments are performed before and after this assembly, including an adjustment to achieve optical accuracy for the various optical systems, an adjustment to achieve mechanical accuracy for the various mechanical systems, and an adjustment to achieve electrical accuracy for the various electrical systems. The process of assembling the exposure apparatus from the various subsystems includes, for example, the mechanical interconnection of the various subsystems, the wiring and connection of electrical circuits, and the piping and connection of the atmospheric pressure circuit. Naturally, prior to performing the process of assembling the exposure apparatus from these various subsystems, there are also the processes of assembling each individual subsystem. When the process of assembling the exposure apparatus from the various subsystems is complete, a comprehensive adjustment is performed to ensure the various accuracies of the exposure apparatus as a whole. Furthermore, it is preferable to manufacture the exposure apparatus in a clean room wherein, for example, the temperature and the cleanliness level are controlled.

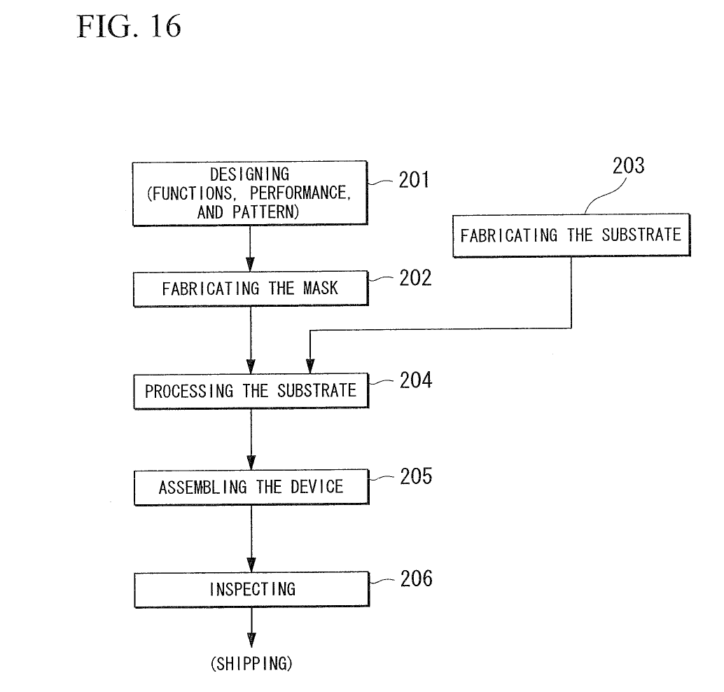

As shown in FIG. 16, a micro-device, such as a semiconductor device, is manufactured by: a step 201 that designs the functions and performance of the micro-device; a step 202 that fabricates a mask (a reticle) based on this designing step; a step 203 that fabricates a substrate, which is the base material of the device; a substrate processing step 204 that comprises a substrate process (exposure process) that includes, in accordance with the embodiments discussed above, exposing the substrate with the exposure light using the mask pattern and developing the exposed substrate; a device assembling step 205 (which includes fabrication processes such as dicing, bonding, and packaging processes); an inspecting step 206; and the like.

Furthermore, the features of each of the embodiments discussed above can be appropriately combined. There are also cases wherein some of the constituent elements are not used. In addition, each disclosure of every Japanese published patent application and U.S. patent related to the exposure apparatus recited in each of the embodiments, modified examples, and the like discussed above is hereby incorporated by reference in its entirety to the extent permitted by the national laws and regulations designated by the present application.

1. A substrate holding apparatus, which holds a substrate that is exposed by exposure light that passes through a liquid, comprising:
an opening; and
a first holding part, which has a holding surface for holding the substrate inside the opening;
wherein,
at least part of an edge part that defines the opening has a first surface and a second surface, which is provided above and is nonparallel to the first surface;
the second surface extends from a boundary part between the first surface and the second surface both upward and toward the outer side with respect to a center of the opening; and
the boundary part between the first surface and the second surface is substantially the same height as or higher than a front surface of the substrate, which is held by the first holding part.

2. A substrate holding apparatus according to claim 1, further comprising:
a third surface, which is formed below and is nonparallel to the first surface;
wherein,
the third surface extends from a boundary part between the first surface and the third surface both downward and toward the outer side with respect to the center of the opening.

3. A substrate holding apparatus according to claim 2, wherein
the third surface is liquid repellent with respect to the liquid.

4. A substrate holding apparatus according to claim 2, wherein
the third surface is formed by a chamfering process.

5. A substrate holding apparatus according to claim 1, wherein
the first surface is substantially perpendicular to the holding surface.

6. A substrate holding apparatus according to claim 1, wherein
the first surface extends from the boundary part between the first surface and the second surface both downward and toward the outer side with respect to the center of the opening.

7. A substrate holding apparatus according to claim 6, wherein
an angle formed between an axis that is perpendicular to the holding surface of the first holding part and the second surface is greater than an angle formed between the axis and the first surface.

8. A substrate holding apparatus according to claim 6, wherein
the first surface is larger than the second surface in directions perpendicular to the holding surface of the first holding part.

9. A substrate holding apparatus according to claim 6, wherein
an angle formed between the first surface and the second surface is 90° or greater.

10. A substrate holding apparatus according to claim 1, further comprising:
a fourth surface, which is substantially parallel to the holding surface;
wherein,
a boundary part between the second surface and the fourth surface is above the boundary part between the first surface and the second surface; and
the fourth surface extends from the boundary part between the second surface and the fourth surface toward the outer side with respect to the center of the opening.

11. A substrate holding apparatus according to claim 10, wherein
the fourth surface is liquid repellent with respect to the liquid.

12. A substrate holding apparatus, which holds a substrate that is exposed by exposure light that passes through a liquid, comprising:
an opening; and
a first holding part, which has a holding surface for holding the substrate inside the opening;
wherein,
at least part of an edge part that defines the opening has a first surface and a second surface, which is provided above the first surface;
the second surface extends from a boundary part between the first surface and the second surface both upward and toward the outer side with respect to a center of the opening; and
the first surface extends from the boundary part between the first surface and the second surface both downward and toward the outer side with respect to a center of the opening.

13. A substrate holding apparatus according to claim 12, wherein
an angle formed between the first surface and the second surface is 90° or greater.

14. A substrate holding apparatus according to claim 12, wherein
an angle formed between an axis that is perpendicular to the holding surface of the first holding part and the second surface is greater than an angle formed between the axis and the first surface.

15. A substrate holding apparatus according to claim 12, wherein
the first surface is larger than the second surface in directions perpendicular to the holding surface of the first holding part.

16. A substrate holding apparatus, which holds a substrate that is exposed by exposure light that passes through a liquid, comprising:
an opening; and
a first holding part, which has a holding surface for holding the substrate inside the opening;
wherein,
at least part of an edge part that defines the opening has a first surface, a second surface, which is provided above the first surface, and a third surface, which is provided below the first surface;
the second surface extends from a boundary part between the first surface and the second surface both upward and toward the outer side with respect to a center of the opening;
the third surface extends from a boundary part between the first surface and the third surface both downward and toward the outer side with respect to the center of the opening; and
an angle formed between an axis perpendicular to the holding surface of the first holding part and the second surface is greater than an angle formed between the axis and the third surface.

17. A substrate holding apparatus according to claim 16, wherein
an angle formed between the second surface and the third surface is 90° or greater.

18. A substrate holding apparatus according to claim 16, wherein
the third surface is larger than the first surface in directions perpendicular to the holding surface of the first holding part.

19. A substrate holding apparatus, which holds a substrate that is exposed by exposure light that passes through a liquid, comprising:
an opening; and
a first holding part, which has a holding surface for holding the substrate inside the opening;
wherein,
at least part of an edge part that defines the opening has a first surface, a second surface, which is provided above the first surface, and a third surface, which is provided below the first surface;
the second surface extends from a boundary part between the first surface and the second surface both upward and toward the outer side with respect to a center of the opening;
the third surface extends from a boundary part between the first surface and the third surface both downward and toward the outer side with respect to the center of the opening; and
the third surface is larger than the first surface in directions perpendicular to the holding surface of the first holding part.

20. A substrate holding apparatus according to claim 19, wherein
an angle formed between an axis that is perpendicular to the holding surface of the first holding part and the second surface is greater than an angle formed between the axis and the third surface.

21. A substrate holding apparatus according to any one of claim 16, wherein
the first surface is substantially perpendicular to the holding surface of the first holding part.

22. A substrate holding apparatus according to claim 12, comprising:
a fourth surface, which is substantially parallel to the holding surface;
wherein,
a boundary part between the second surface and the fourth surface is above the boundary part between the first surface and the second surface; and
the fourth surface extends from the boundary part between the second surface and the fourth surface toward the outer side with respect to the center of the opening.

23. A substrate holding apparatus according to claim 22, wherein
the fourth surface is liquid repellent with respect to the liquid.

24. A substrate holding apparatus according to claim 22, wherein
the fourth surface is substantially the same height as a front surface of the substrate, which is held by the first holding part.

25. A substrate holding apparatus according to claim 1, wherein
the first surface is liquid repellent with respect to the liquid.

26. A substrate holding apparatus according to claim 1, wherein
the second surface is liquid repellent with respect to the liquid.

27. A substrate holding apparatus according to claim 1, wherein
the first holding part holds the substrate so that a side surface of the substrate and at least part of the first surface oppose one another with a gap interposed therebetween.

28. A substrate holding apparatus according to claim 27, wherein
the side surface of the substrate includes a liquid repellent area that is liquid repellent with respect to the liquid; and
at least part of the first surface opposes the liquid repellent area.

29. A substrate holding apparatus according to claim 27, wherein
the first surface is provided substantially along the side surface of the substrate, which is held by the first holding part.

30. A substrate holding apparatus according to claim 27, wherein
the side surface of the substrate includes:
a perpendicular area, which is substantially perpendicular to the front surface of the substrate;
an upper area that links an upper end of the perpendicular area and a front surface of the substrate; and
a lower area that links a lower end of the perpendicular area and a rear surface of the substrate; and
the first holding part holds the substrate so that the front surface of the substrate is substantially parallel to the holding surface.

31. A substrate holding apparatus according to claim 1, further comprising:
a second holding part that releasably holds a plate member;
wherein,
the opening is provided around the first holding part by the holding of the plate member by the second holding part.

32. A substrate holding apparatus according to claim 31, wherein
the plate member has the opening.

33. A substrate holding apparatus according to claim 1, wherein
the second surface is formed by a chamfering process.

34. A substrate holding apparatus, which holds a substrate that is exposed by exposure light that passes through a liquid, comprising:
an opening; and
a first holding part, which has a holding surface for holding the substrate inside the opening;
wherein,
at least part of an edge part that defines the opening has a first inclined surface part and a second inclined surface part, which is provided above the first inclined surface part;
the more spaced apart the first inclined surface part becomes from the substrate held by the first holding part, the lower it becomes;
the more spaced apart the second inclined surface part becomes from the substrate held by the first holding part, the higher it becomes; and
the first inclined surface part is larger than the second inclined surface part in directions that are perpendicular to the holding surface of the first holding part.

35. A substrate holding apparatus according to claim 34, wherein
an angle formed between the first inclined surface part and the second inclined surface part is 90° or greater.

36. A substrate holding apparatus according to claim 34, wherein
the angle formed between the first inclined surface part and an axis that is perpendicular to the holding surface is less than an angle formed between the second inclined surface part and the axis.

37. A substrate holding apparatus according to claim 34, wherein
the first inclined surface part and the second inclined surface part are liquid repellent with respect to the liquid.

38. An exposure apparatus that exposes a substrate through a liquid, comprising:
a substrate holding apparatus according to claim 1;
wherein,
the substrate is held by the substrate holding apparatus.

39. A device fabricating method, comprising:
exposing a substrate using the exposure apparatus according to claim 38; and developing the exposed substrate.

40. An exposing method, comprising:
holding a substrate by a substrate holding apparatus according to claim 1, and
radiating exposure light to the substrate, which is held by the substrate holding apparatus, through a liquid.

41. A device fabricating method, comprising:
exposing a substrate using an exposing method according to claim 40; and developing the exposed substrate.

42. A plate member, which is disposed around a substrate that is exposed through a liquid, comprising:
an opening, which is for disposing the substrate therein; and
a front surface, which is formed around the opening;
wherein,
at least part of an edge part, which defines the opening, has a first surface and a second surface, which is provided so that it adjoins the first surface;
the first surface extends from a boundary part between the first surface and the second surface both in a first direction that is perpendicular to the front surface and toward the outer side with respect to a center of the opening; and
the second surface extends from the boundary part between the first surface and the second surface both in a second direction, which is the opposite of the first direction, and toward the outer side with respect to the center of the opening.

43. A plate member, which is disposed around a substrate that is exposed through a liquid, comprising:
an opening, which is for disposing the substrate therein; and
a front surface, which is formed around the opening;
wherein,
at least part of an edge part, which defines the opening, has a first surface, a second surface, which is provided adjoining one side of the first surface, and a third surface, which is provided adjoining another side of the first surface;
the second surface extends from a boundary part between the first surface and the second surface both in a first direction that is perpendicular to the front surface and toward the outer side with respect to a center of the opening;
the third surface extends from a boundary part between the first surface and the third surface both in a second direction, which is the opposite of the first direction, and toward the outer side with respect to the center of the opening; and
an angle formed between an axis that is perpendicular to the front surface and the second surface is larger than an angle formed between the axis and the third surface.

44. A plate member, which is disposed around a substrate that is exposed through a liquid, comprising:
an opening, which is for disposing the substrate therein; and
a front surface, which is formed around the opening;
wherein,
at least part of an edge part, which defines the opening, has a first surface, a second surface, which is provided adjoining one side of the first surface, and a third surface, which is provided adjoining another side of the first surface;
the second surface extends from a boundary part between the first surface and the second surface both in a first direction that is perpendicular to the front surface and toward the outer side with respect to a center of the opening;
the third surface extends from a boundary part between the first surface and the third surface both in a second direction, which is the opposite of the first direction, and toward the outer side with respect to the center of the opening; and
the third surface is larger than the first surface in directions that are parallel to the first and second directions.

45. A wall that surrounds at least a part of a substrate in an immersion exposure apparatus, the wall comprising:
a first gradient surface that has a declination to the substrate; and
a corner that is at a lower end of the first gradient surface and that is relatively near to the substrate, the corner being located at a substantially same height position as a surface of the substrate or at a higher position than the surface of the substrate.

46. A wall according to claim 45, further comprising:
a substantially vertical surface that is lower than the first gradient surface and that is substantially along a thickness direction of the substrate; and
a second gradient surface that is lower than the substantially vertical surface and that has a inclination up to the substrate.

47. A wall according to claim 45, wherein a length of the substantially vertical surface in a thickness direction of the substrate is greater than that of the first gradient surface.

48. A wall according to claim 45, wherein an angle between the first gradient surface and the substantially vertical surface is 90° or greater.

49. A wall according to claim 46, wherein the second gradient surface has a liquid repellency with respect to a liquid.

50. A wall according to claim 45, further comprising:
a second gradient surface that is lower than the first gradient surface and that has a inclination up to the substrate, the second gradient surface joining together with the first gradient surface at the corner.

51. A wall according to claim 50, wherein an angle between the first gradient surface and an axis along a thickness direction of the substrate is greater than an angle between the second gradient surface and the axis.

52. A wall according to any one of claim 45, further comprising:
a substantially horizontal surface that is above the first gradient surface and that has a liquid repellency with respect to a liquid, the substantially horizontal surface being along a direction orthogonal to a thickness direction of the substrate.

53. A wall that surrounds at least a part of a substrate in an immersion exposure apparatus, the wall comprising:
a first gradient portion that has a declination to the substrate;
a second gradient portion that is lower than the first gradient portion and has a inclination up to the substrate; and
a corner that is at a lower end of the first gradient portion and that is substantially nearest to the substrate, the corner located at a height position relatively near to a surface of the substrate.

54. A wall according to claim 53, wherein a length of the second gradient portion in a thickness direction of the substrate is greater than that of the first gradient portion.

55. A wall according to claim 53, wherein an angle between surfaces of the first and the second gradient portions is 90° or greater.

56. A wall according to claim 54, wherein an angle between the declination of the first gradient portion and an axis along a thickness direction of the substrate is greater than an angle between the inclination of the second gradient portion and the axis.

57. A wall according to claim 53, wherein the declination of the first gradient portion, the inclination of the second gradient portion, and the corner form a contour along a thickness direction of the substrate, that substantially projects toward the substrate.

58. A wall according to claim 57, wherein the contour has a substantially non-symmetrically shape with respect to an axis orthogonal to the thickness direction of the substrate.

59. A wall according to claim 53, wherein at least a part of surfaces of the first and the second gradient portions has a liquid repellency with respect to a liquid.

60. A wall according to claim 53, wherein a surface of the first gradient portion joins together with a surface of the second gradient portion at the corner.

61. A wall according to claim 53, further comprising:
a substantially vertical portion that is disposed between the first gradient portion and the second gradient portion and that is substantially along a thickness direction of the substrate.

62. A wall according to claim 61, wherein a surface of the substantially vertical portion has a liquid repellency with respect to a liquid.

63. A wall according to claim 53, further comprising:
a substantially horizontal portion that is above the first gradient portion and that has a liquid repellency with respect to a liquid, the substantially horizontal portion being along a direction orthogonal to a thickness direction of the substrate.
